(19) United States
(12) Patent Application Publication
(10) Pub. No.: US 2025/0233057 A1
(43) Pub. Date: Jul. 17, 2025

(54) JOINING STRUCTURE AND SEMICONDUCTOR DEVICE

(71) Applicant: Rohm Co., Ltd., Kyoto-shi (JP)

(72) Inventors: Oji SATO, Kyoto-shi (JP); Tomohiro YASUNISHI, Kyoto-shi (JP); Tetsuya SHIMIZU, Kyoto-shi (JP)

(21) Appl. No.: 19/097,574

(22) Filed: Apr. 1, 2025

Related U.S. Application Data
(63) Continuation of application No. PCT/JP2023/033925, filed on Sep. 19, 2023.

(30) Foreign Application Priority Data
Oct. 4, 2022 (JP) 2022-159985

(51) Int. Cl. H01L 23/495; H01L 23/367; H01L 23/40

(52) U.S. Cl. CPC H01L 23/49582; H01L 23/3677; H01L 23/40; H01L 23/49548; H01L 23/49562; H01L 23/49568

(57) ABSTRACT

A joining structure includes: a first bonding target including a first bonding layer; a second bonding target including a second bonding layer; and an intermediate bonding material interposed between the first bonding target and the second bonding target. The intermediate bonding material includes a base layer, and a first surface layer and a second surface layer disposed on respective sides of the base layer. The first bonding layer and the first surface layer are joined to each other by solid-phase bonding. The second bonding layer and the second surface layer are joined to each other by solid-phase bonding. The base layer contains Cu as a main component.

### TECHNICAL FIELD

The present disclosure relates to a joining structure and a semiconductor device.

### BACKGROUND ART

Semiconductor devices provided with power switching elements, such as metal oxide semiconductor field effect transistors (MOSFETs) and insulated gate bipolar transistors (IGBTs), have been conventionally known. These semiconductor devices are used in various electronics, ranging from industrial devices to home appliances and information terminals, or even to vehicle-mount devices. JP-A-2015-126342 discloses a conventional semiconductor device (a power module). The power module disclosed in JP-A-2015-126342 includes a plurality of transistors, a main substrate, a signal substrate, and a signal terminal. The transistors are disposed on the main substrate.

### BRIEF DESCRIPTION OF THE DRAWINGS

FIG. 1 is a perspective view showing a semiconductor device according to a first embodiment of the present disclosure.

FIG. 2 is a partial perspective view showing the semiconductor device according to the first embodiment of the present disclosure.

FIG. 3 is a partial perspective view showing the semiconductor device according to the first embodiment of the present disclosure.

FIG. 4 is a plan view showing the semiconductor device according to the first embodiment of the present disclosure.

FIG. 5 is a partial plan view showing the semiconductor device according to the first embodiment of the present disclosure.

FIG. 6 is a partial right-side view showing the semiconductor device according to the first embodiment of the present disclosure.

FIG. 7 is a partial left-side view showing the semiconductor device according to the first embodiment of the present disclosure.

FIG. 8 is a partial plan view showing the semiconductor device according to the first embodiment of the present disclosure.

FIG. 9 is a right-side view showing the semiconductor device according to the first embodiment of the present disclosure.

FIG. 10 is a bottom view showing the semiconductor device according to the first embodiment of the present disclosure.

FIG. 11 is a cross-sectional view along line XI-XI in FIG. 5.

FIG. 12 is a cross-sectional view along line XII-XII in FIG. 5.

FIG. 13 is a partially enlarged cross-sectional view showing a part of FIG. 12.

FIG. 14 is a partially enlarged cross-sectional view showing an example of a mounting structure according to the first embodiment of the present disclosure.

FIG. 15 is a partially enlarged cross-sectional view showing another example of the mounting structure according to the first embodiment of the present disclosure.

FIG. 16 is a partially enlarged cross-sectional view showing a part of FIG. 12.

FIG. 17 is a partially enlarged cross-sectional view showing another example of the mounting structure according to the first embodiment of the present disclosure.

FIG. 18 is a partially enlarged cross-sectional view showing another example of the mounting structure according to the first embodiment of the present disclosure.

FIG. 19 is a cross-sectional view along line XIX-XIX in FIG. 5.

FIG. 20 is a cross-sectional view along line XX-XX in FIG. 5.

FIG. 21 is a cross-sectional view along line XXI-XXI in FIG. 5.

FIG. 22 is a cross-sectional view along line XXII-XXII in FIG. 5.

FIG. 23 is a partial right-side view showing a first variation of the semiconductor device according to the first embodiment of the present disclosure.

FIG. 24 is a partially enlarged cross-sectional view showing another example of the mounting structure according to the first embodiment of the present disclosure.

FIG. 25 is a partially enlarged cross-sectional view showing a mounting structure according to a second embodiment of the present disclosure.

### DETAILED DESCRIPTION OF EMBODIMENTS

The following describes preferred embodiments of a semiconductor device according to the present disclosure with reference to the drawings. In the following description, the same or similar elements are denoted by the same reference numerals and redundant descriptions of such elements are omitted. In the present disclosure, terms such as “first”, “second”, “third” and so on are used merely for identification and not intended to impose ordinal requirements on the objects referred to by these terms.

In the description of the present disclosure, the expressions “an object A is formed in an object B” and “an object A is formed on an object B” imply the situation where, unless otherwise specifically noted, “the object A is formed directly in or on the object B”, and “the object A is formed in or on the object B, with another object interposed between the object A and the object B”. Likewise, the expressions “an object A is arranged in an object B”, and “an object A is arranged on an object B” imply the situation where, unless otherwise specifically noted, “the object A is arranged directly in or on the object B”, and “the object A is arranged in or on the object B, with another object interposed between the object A and the object B”. Further, the expression “an object A is located on an object B” implies the situation where, unless otherwise specifically noted, “the object A is located on the object B, in contact with the object B”, and “the object A is located on the object B, with another object interposed between the object A and the object B”. Still further, the expression “an object A overlaps with an object B as viewed in a certain direction” implies the situation where, unless otherwise specifically noted, “the object A overlaps with the entirety of the object B”, and “the object A overlaps with a part of the object B”.

### Semiconductor Device A1:

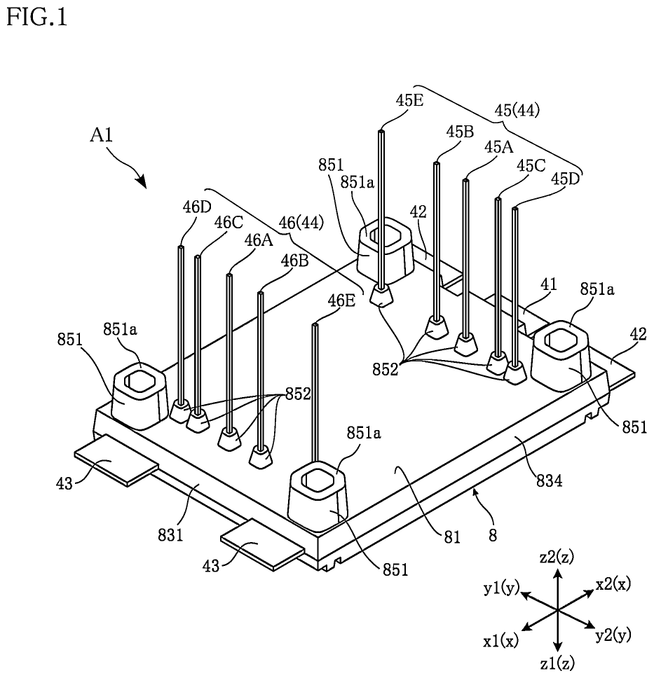

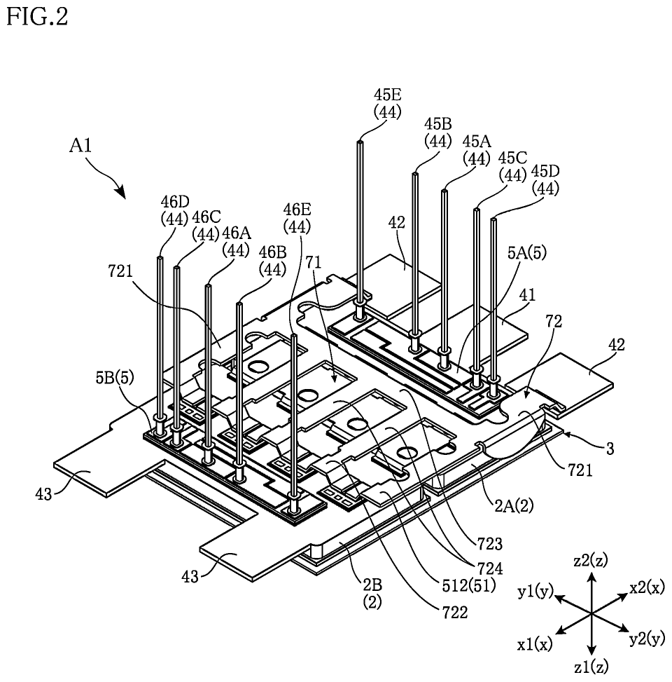

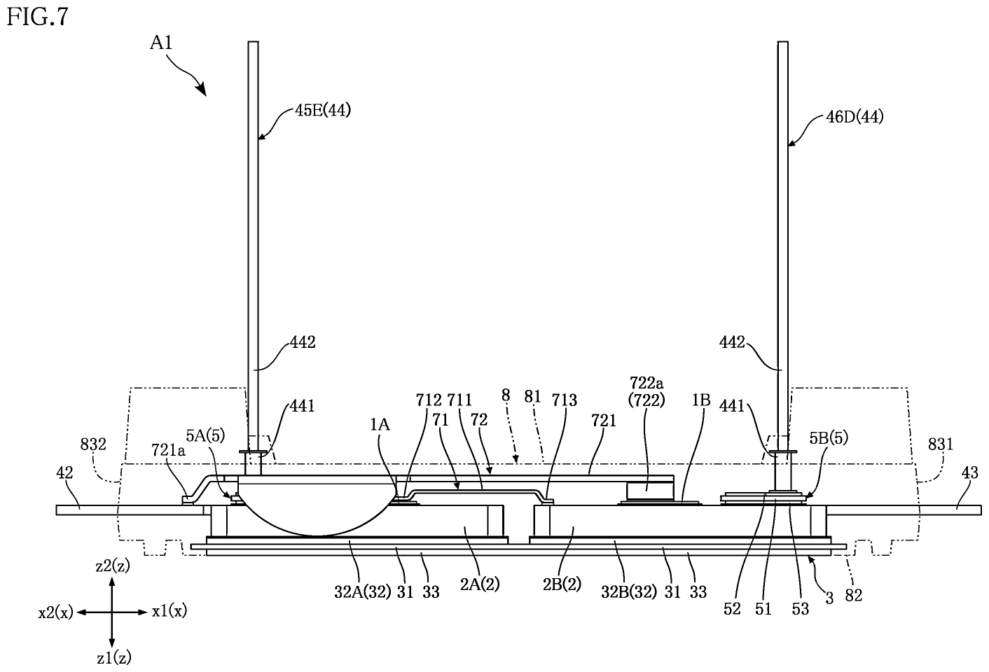

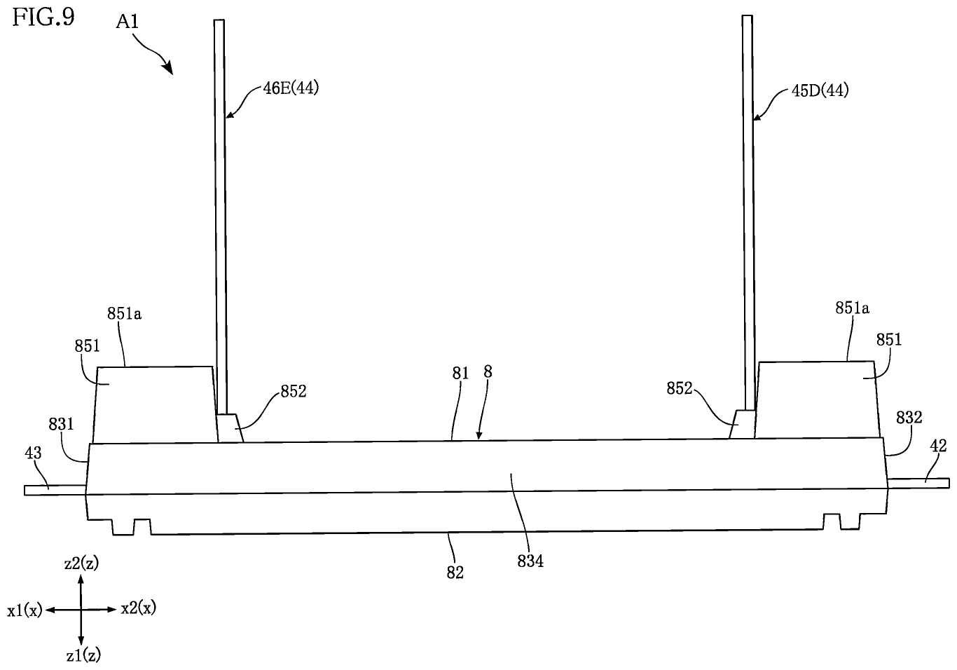

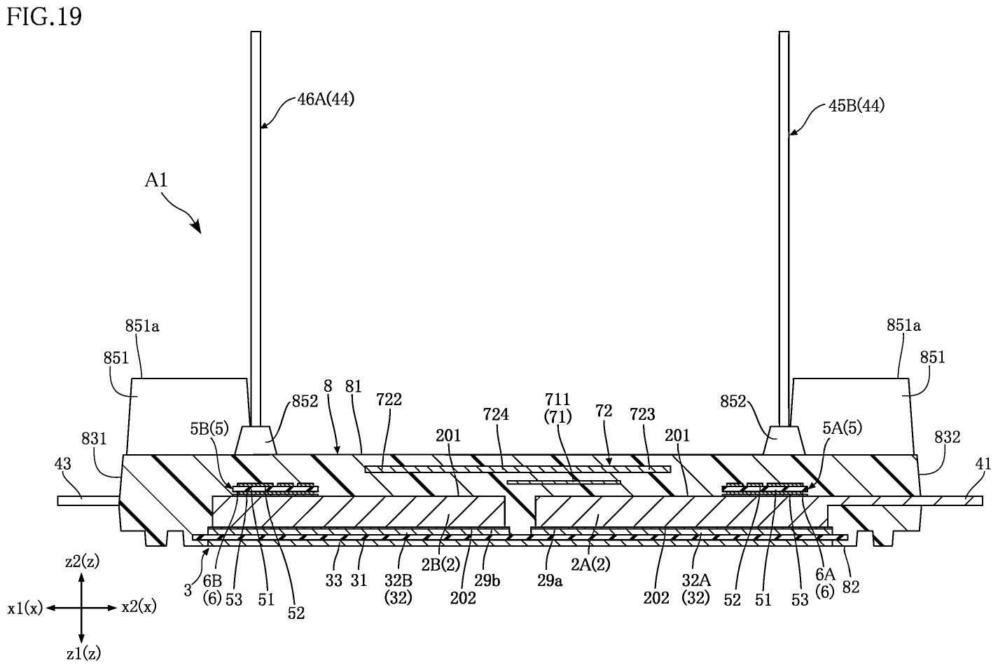

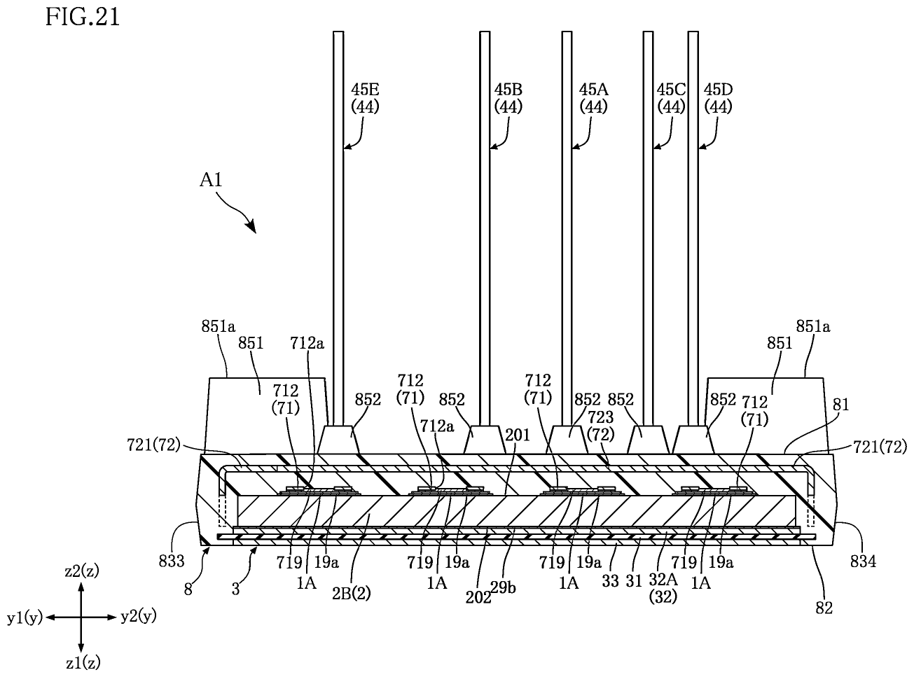

FIGS. 1 to 22 show a semiconductor device A1 according to an embodiment of the present disclosure. The semiconductor device A1 includes a plurality of semiconductor elements 1, a supporting conductor 2, a supporting substrate 3, a plurality of power terminals 41 to 43, a plurality of control terminals 44, a signal substrate 5, an adhesive layer 6, a first conductive member 71, a second conductive member 72, a plurality of wires 73 to 76, a resin member 8, and a resin-filled part 88. The semiconductor device A1 also includes joining structures B1 to B4.

The supporting conductor 2 includes a first conductive part 2A and a second conductive part 2B. The control terminals 44 include a plurality of first control terminals 45 and a plurality of second control terminals 46. The signal substrate 5 includes a first signal substrate 5A and a second signal substrate 5B. The adhesive layer 6 includes a first adhesive body 6A and a second adhesive body 6B.

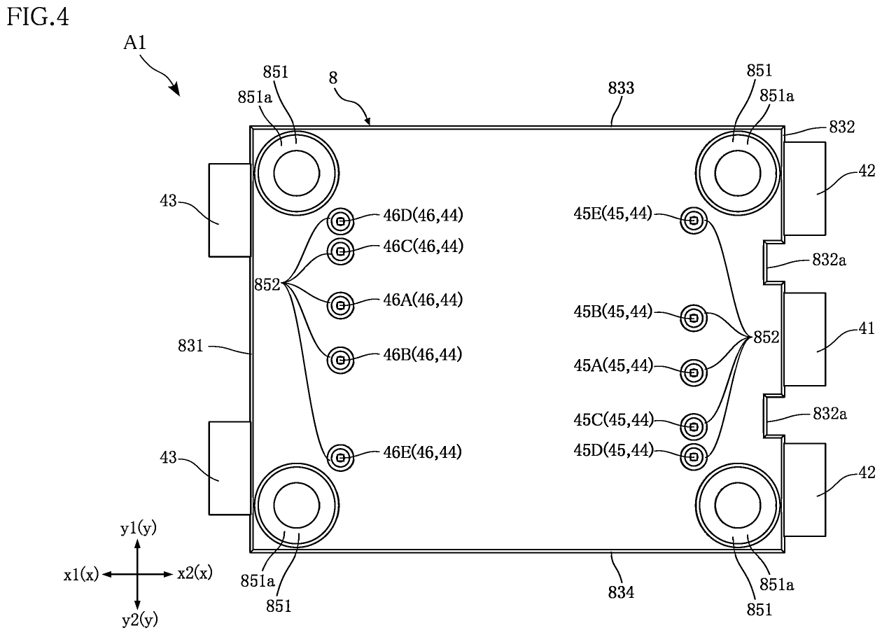

For the convenience of description, three mutually orthogonal directions are referred to as x, y and z directions. In one example, the z direction is the thickness direction of the semiconductor device A1. The x direction is the horizontal direction in plan view of the semiconductor device A1 (see FIG. 4). The y direction is the vertical direction in plan view of the semiconductor device A1 (see FIG. 4). In the following description, a “plan view” refers to the view as seen in the z direction. Note that terms such as “top”, “bottom”, “upward”, “downward”, “upper surface”, and “lower surface” are merely used to describe the relative positions of elements and components with respect to the z direction, and not necessarily with respect to the gravitational vertical. The x direction is an example of the “first direction” of the present disclosure.

### Semiconductor Elements 1

The semiconductor elements 1 are electronic components integral to the function of the semiconductor device A1. The semiconductor elements 1 are made of a semiconductor material, such as a material containing silicon carbide (SiC) as a main component. The semiconductor material is not limited to SiC and may be silicon (Si), gallium nitride (GaN), or diamond (C). Note that the semiconductor elements 1 are power semiconductor chips having a switching function, and metal oxide semiconductor field effect transistors (MOSFETs) are one example. Although the semiconductor elements 1 in the present embodiment are MOSFETs, the semiconductor elements 1 may be other types of transistors, such as insulated gate bipolar transistors (IGBTs). All of the semiconductor elements 1 are of the same type. For example, the semiconductor elements 1 are n-channel MOSFETs, but may be p-channel MOSFETs in another example.

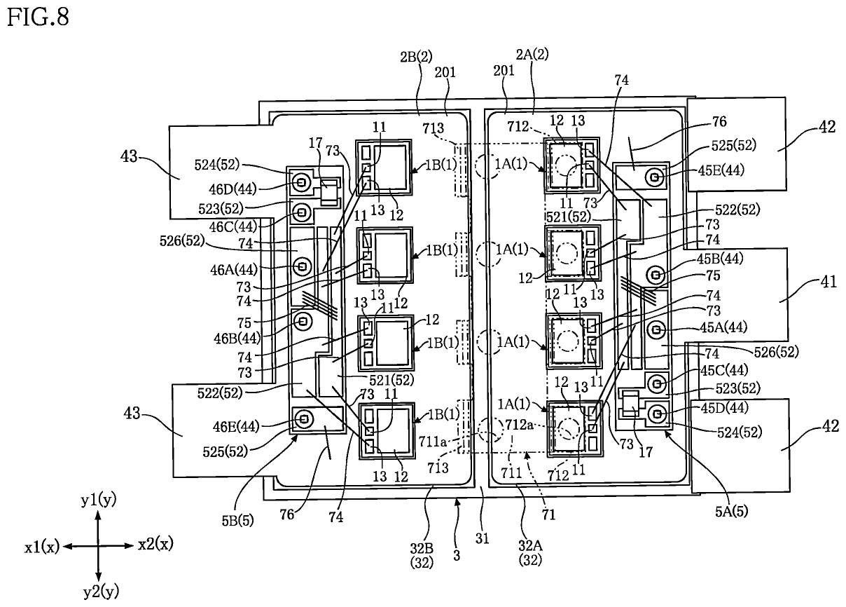

The semiconductor elements 1 include a plurality of first switching elements 1A and a plurality of second switching elements 1B. As shown in FIG. 8, the semiconductor device A1 includes four first switching elements 1A and four second switching elements 1B. The respective numbers of first switching elements 1A and second switching elements 1B are not limited to four and can be changed appropriately depending on the performance desired for the semiconductor device A1. The number of first switching elements 1A may be the same as or different from the number of second switching elements 1B. The numbers of first switching elements 1A and second switching elements 1B are determined by the current carrying capacity of the semiconductor device A1.

In one example, the semiconductor device A1 is configured as a half-bridge switching circuit. In this case, the first switching elements 1A form the upper arm circuit of the semiconductor device A1, and the second switching elements 1B form the lower arm circuit of the semiconductor device A1. The first switching elements 1A forming the upper arm circuit are connected to each other in parallel, and the second switching elements 1B forming the lower arm circuit are connected to each other in parallel. In addition, each first switching element 1A and a relevant second switching element 1B are connected in series.

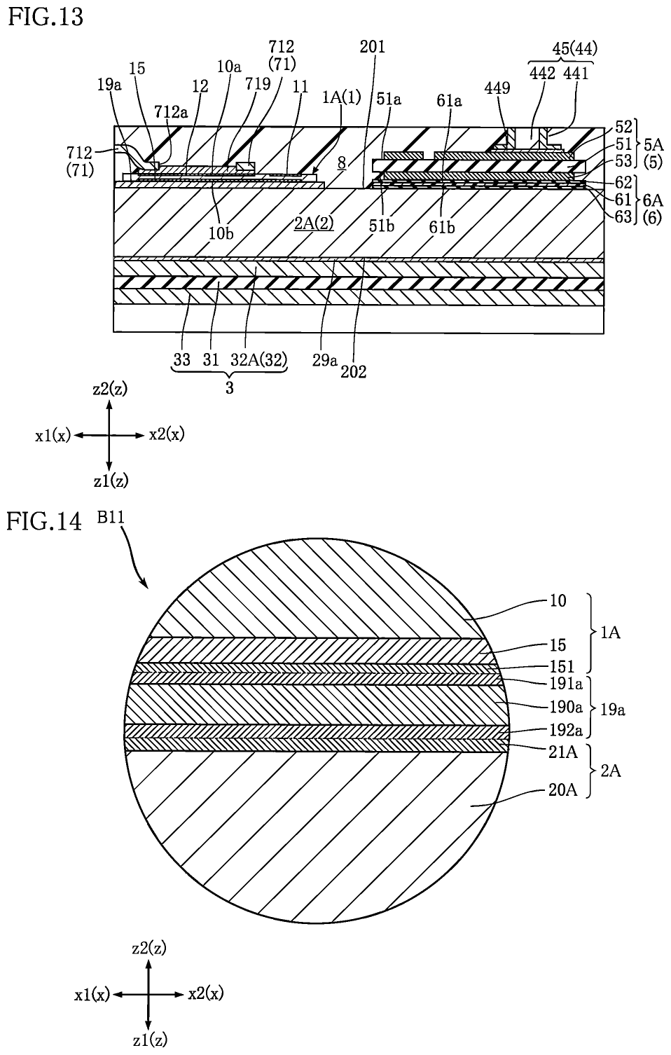

As shown in FIGS. 13 and 16, each of the semiconductor elements 1 (the first switching elements 1A and the second switching elements 1B) has an element obverse surface 10a and an element reverse surface 10b. The element obverse surface 10a and the element reverse surface 10b of each semiconductor element 1 are spaced apart from each other in the z direction. The element obverse surface 10a faces the z2 side and the element reverse surface 10b faces the z1 side.

As shown in FIGS. 8, 12, 13, and 21, for example, the first switching elements 1A are mounted on the supporting conductor 2 (the first conductive part 2A). In the example shown in FIG. 8, the first switching elements 1A are aligned in the y direction and spaced apart from each other. Each of the first switching elements 1A are electrically bonded to the supporting conductor 2 (the first conductive part 2A) via an intermediate bonding material 19a. Each first switching element 1A is bonded to the first conductive part 2A with the element reverse surface 10b facing the supporting conductor 2 (the first conductive part 2A).

As shown in FIGS. 8, 12, 16, and 20, for example, the second switching elements 1B are mounted on the supporting conductor 2 (the second conductive part 2B). In the example shown in FIG. 8, the second switching elements 1B are aligned in the y direction and spaced apart from each other. Each of the second switching elements 1B are electrically bonded to the supporting conductor 2 (the second conductive part 2B) via an intermediate bonding material 19b. Each second switching element 1B is bonded to the second conductive part 2B with the element reverse surface 10b facing the supporting conductor 2 (the second conductive part 2B). As can be seen from FIG. 8, the first switching elements 1A overlap with the second switching elements 1B as viewed in the x direction. In a different example, the first switching elements 1A and the second switching elements 1B may be arranged without overlap as viewed in the x direction.

As shown in FIGS. 8, 13, and 16, each of the semiconductor elements 1 (the first switching elements 1A and the second switching elements 1B) includes a first obverse-surface electrode 11, a second obverse-surface electrode 12, a third obverse-surface electrode 13, and a reverse-surface electrode 15. The description given below of the first obverse-surface electrode 11, the second obverse-surface electrode 12, the third obverse-surface electrode 13, and the reverse-surface electrode 15 is commonly applied to all the semiconductor elements 1. The first obverse-surface electrode 11, the second obverse-surface electrode 12, and the third obverse-surface electrode 13 are disposed on the element obverse surface 10a. The first obverse-surface electrode 11, the second obverse-surface electrode 12, and the third obverse-surface electrode 13 are insulated from each other by an insulating film not shown in the figures. The reverse-surface electrode 15 is disposed on the element reverse surface 10b. The reverse-surface electrode 15 covers the entire region (or substantially the entire region) of the element reverse surface 10b. The reverse-surface electrode 15 is formed by plating with silver (Ag), for example.

In an example in which MOSFETs are used as the semiconductor elements 1, the first obverse-surface electrode 11 may be a gate electrode that receives an input of a drive signal (e.g., gate voltage) for driving the semiconductor element 1. The second obverse-surface electrode 12 may be a source electrode through which a source current flows. The third obverse-surface electrode 13 may be a source-sense electrode that is held at the same potential as the second obverse-surface electrode 12. That is, the third obverse-surface electrode 13 passes the same source current as the second obverse-surface electrode 12. The reverse-surface electrode 15 may be a drain electrode through which a drain current flows.

Each of the semiconductor elements 1 switches between a conducting state and a non-conducting state in response to a drive signal (gate voltage) inputted to the first obverse-surface electrode 11 (the gate electrode). This operation of the semiconductor element 1 changing between the conducting state and the non-conducting state is called a switching operation. In the conducting state, a forward current flows from the reverse-surface electrode 15 (the drain electrode) to the second obverse-surface electrode 12 (the source electrode). In the non-conducting state, no forward current flows. By the functions of the semiconductor elements 1, the semiconductor device A1 converts a first power supply voltage (e.g., direct-current voltage) into a second power supply voltage (e.g., alternating current voltage). The first power supply voltage is inputted to (applied between) the power terminal 41 and each of the two power terminals 42, and the second power supply voltage is inputted (applied) to the two power terminals 43.

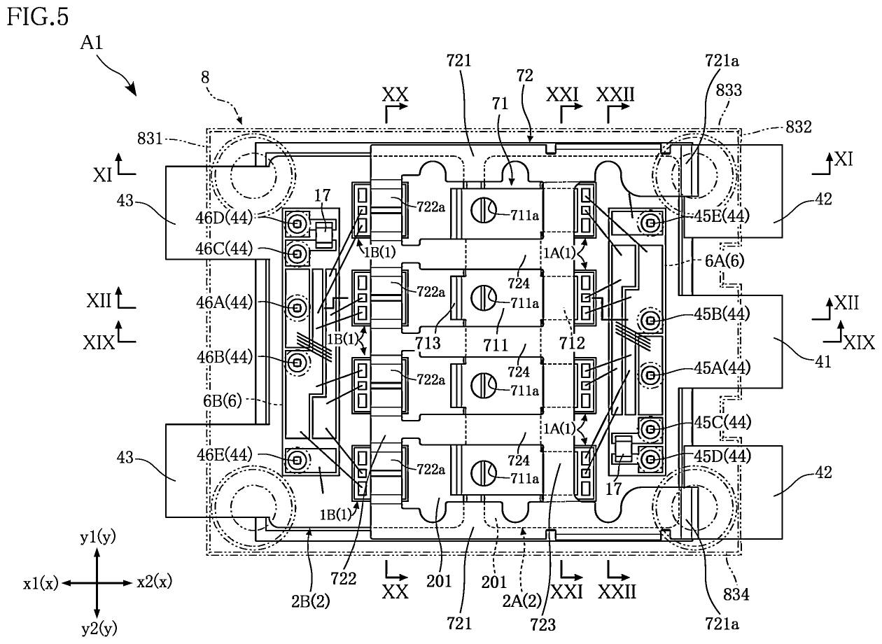

As shown in FIGS. 5 and 8, for example, the semiconductor device A1 includes two thermistors 17. The thermistors 17 are used as temperature detection sensors.

### Supporting Conductor 2:

The supporting conductor 2 supports the semiconductor elements 1 (the first switching elements 1A and the second switching elements 1B). The supporting conductor 2 is bonded to the supporting substrate 3. The supporting conductor 2 is rectangular in plan view, for example. The supporting conductor 2, together with the first conductive member 71 and the second conductive member 72, forms a path for the main circuit current that is switched on and off by the first switching elements 1A and the second switching elements 1B.

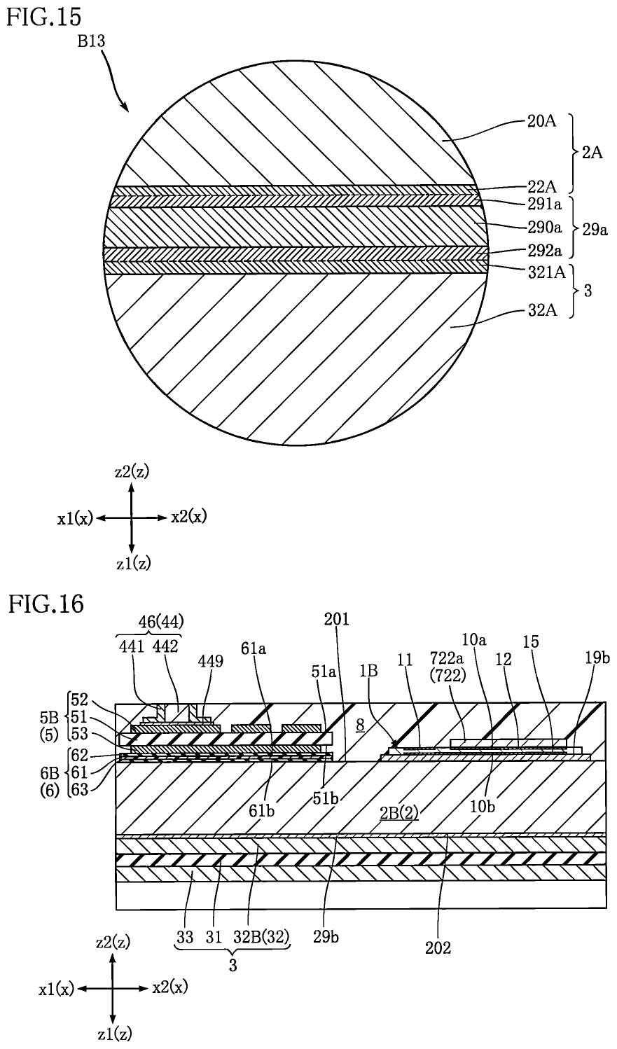

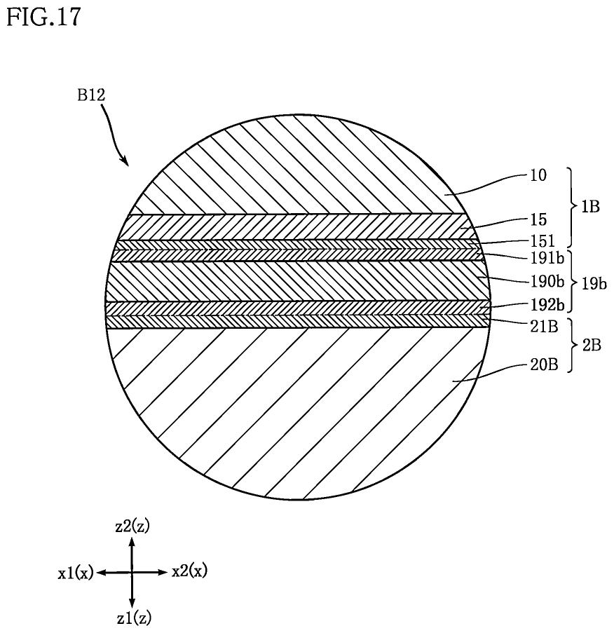

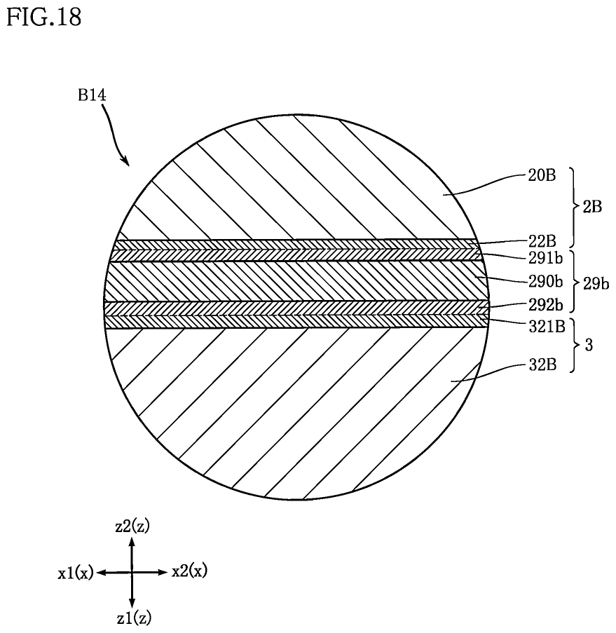

The supporting conductor 2 includes the first conductive part 2A and the second conductive part 2B. As shown in FIGS. 14 and 15, the first conductive part 2A includes a body layer 20A, a bonding layer 21A, and a bonding layer 22A. As shown in FIGS. 17 and 18, the second conductive part 2B includes a body layer 20B, a bonding layer 21B, and a bonding layer 22B. Each of the body layer 20A and the body layer 20B is a plate-like member made of metal. The metal is copper (Cu) or a Cu alloy. The specific configurations of the bonding layer 21A, the bonding layer 22A, the bonding layer 21B, and the bonding layer 22B are described below. The first conductive part 2A and the second conductive part 2B, together with the power terminals 41 to 43, form conductive paths leading to the first switching elements 1A and the second switching elements 1B. The first conductive part 2A and the second conductive part 2B are rectangular in plan view, for example. Each of the first conductive part 2A and the second conductive part 2B may have a dimension of at least 15 mm and at most 25 mm in the x direction, a dimension of at least 30 mm and at most 40 mm in the y direction, and a dimension of at least 1.0 mm and at most 5.0 mm (preferably a dimension of about 2.0 mm) in the z direction. These dimensions of the first conductive part 2A and the second conductive part 2B are non-limiting examples and can be changed appropriately depending on the specifications of the semiconductor device A1.

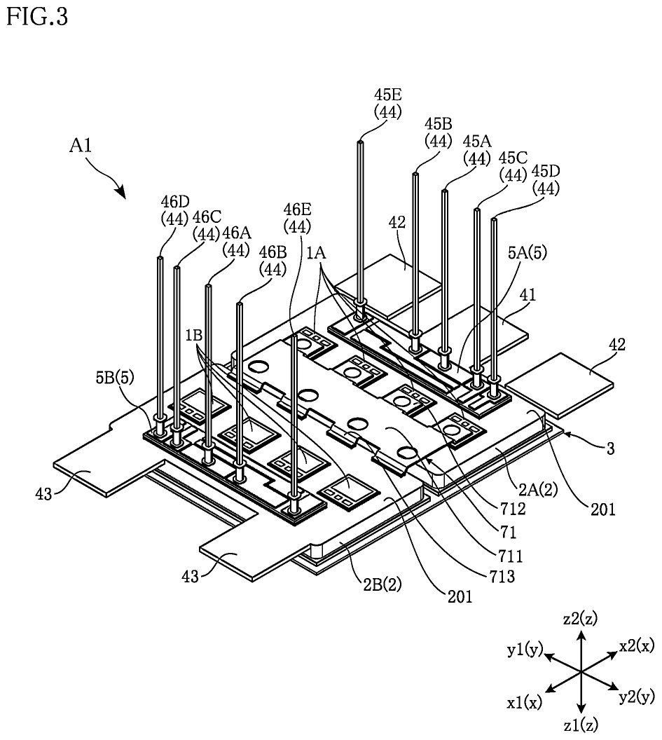

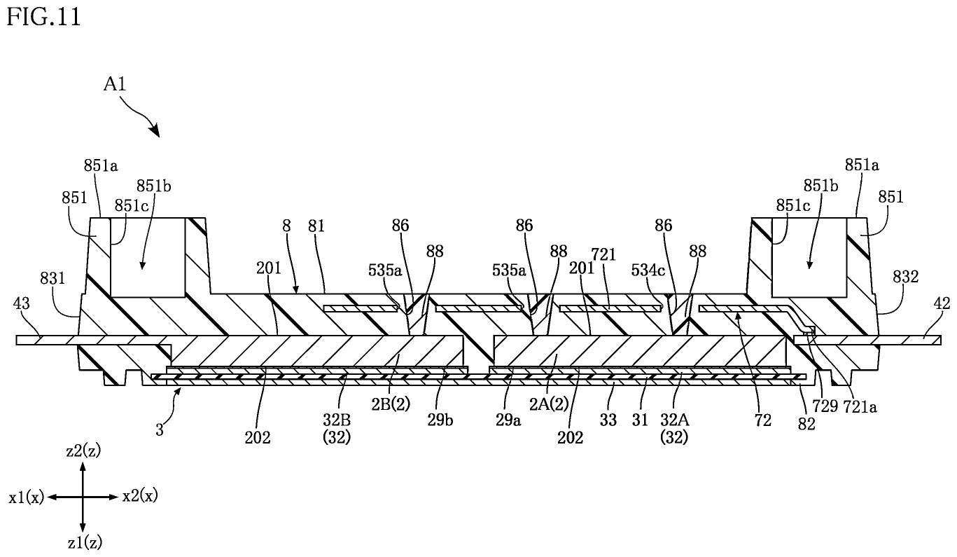

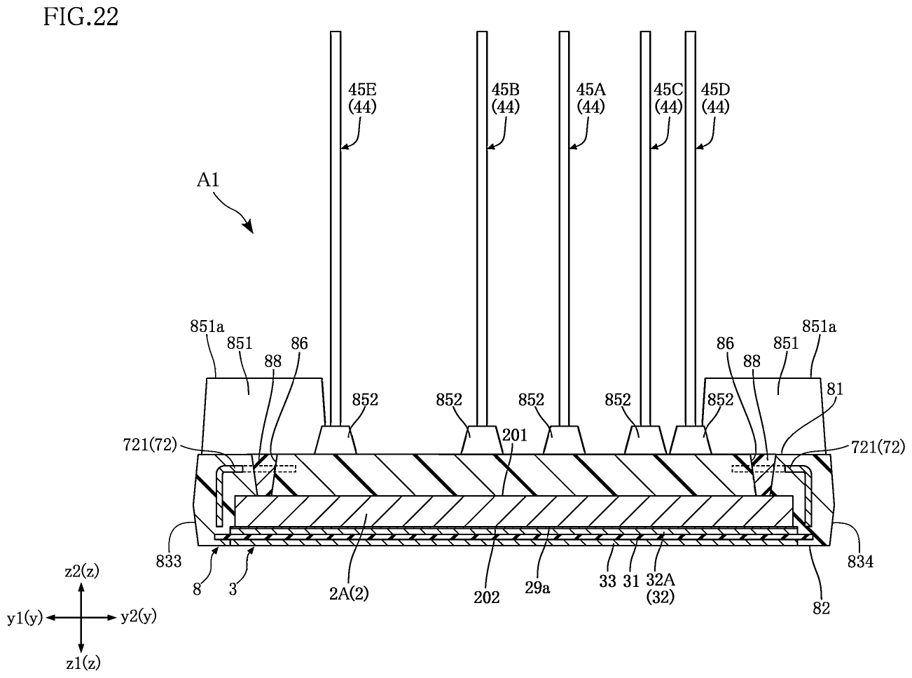

As shown in FIGS. 11 and 22, the first conductive part 2A is bonded to the supporting substrate 3 via an intermediate bonding material 29a, and the second conductive part 2B is bonded to the supporting substrate 3 via an intermediate bonding material 29b. The first conductive part 2A has the first switching elements 1A bonded thereto via the intermediate bonding material 19a. The second conductive part 2B has the second switching elements 1B bonded thereto via the intermediate bonding material 19b. As shown in FIGS. 3, 8, 11, 12, and 19, the first conductive part 2A and the second conductive part 2B are spaced apart from each other in the x direction. In the example shown in these figures, the first conductive part 2A is located on the x1 side relative to the second conductive part 2B. As viewed in the x direction, the first conductive part 2A and the second conductive part 2B overlap with each other.

The supporting conductor 2 (each of the first conductive part 2A and the second conductive part 2B) has an obverse surface 201 and a reverse surface 202. As shown in FIGS. 11 to 22, the obverse surface 201 and the reverse surface 202 are spaced apart from each other in the z direction. The obverse surface 201 faces the z2 side, and the reverse surface 202 faces the z1 side. The reverse surface 202 faces the supporting substrate 3.

### Joining Structures B11 and B12:

As shown in FIG. 14, the semiconductor device A1 includes a joining structure B11. The joining structure B11 is a structure in which a first switching element 1A as a first bonding target is bonded to the first conductive part 2A as a second bonding target via an intermediate bonding material 19a.

The intermediate bonding material 19a includes a base layer 190a, a first surface layer 191a, and a second surface layer 192a.

The base layer 190a contains copper (Cu) as a main component. Examples of the configuration where the base layer 190a contains copper (Cu) as a main component include a configuration with copper (Cu) alone, a configuration in which an additive metal or the like is added to copper (Cu), and a configuration with various copper (Cu) alloys. The same applies to the configuration where “an element contains a certain metal as a main component” described below. The thickness of the base layer 190a is not particularly limited. In the present embodiment, the base layer 190a is thicker than each of the first surface layer 191a and the second surface layer 192a. The thickness of the base layer 190a is at least 50 μm and at most 300 μm, for example.

The first surface layer 191a is disposed on the surface of the base layer 190a on the z2 side in the z direction. The first surface layer 191a is joined to the first switching element 1A by solid-state bonding. The solid-state bonding is a method of applying pressure and heat to two layers that contain the same metal as a main component, and that are in direct contact with each other. Examples of the method include solid-phase diffusion bonding and solid-phase deformation bonding. In the present embodiment, the first surface layer 191a mainly contains silver (Ag). The thickness of the first surface layer 191a is not particularly limited. In the present embodiment, the first surface layer 191a is thinner than the base layer 190a. The thickness of the first surface layer 191a is at least 0.1 μm and at most 15 μm, for example.

In the present embodiment, the first switching element 1A further includes a bonding layer 151. The bonding layer 151 corresponds to a first bonding layer in the joining structure B11. The bonding layer 151 is disposed on the surface of the reverse-surface electrode 15 on the z1 side in the z direction. The bonding layer 151 is joined to the first surface layer 191a by solid-state bonding. In the present embodiment, the bonding layer 151 mainly contains silver (Ag). The thickness of the bonding layer 151 is not particularly limited, and may be at least 0.01 μm and at most 5 μm.

The main component of each of the first surface layer 191a and the bonding layer 151 is not limited to a particular metal, as long as the metal allows the first surface layer 191a and the bonding layer 151 to be joined by solid-state bonding.

The boundary between the first surface layer 191a and the bonding layer 151 that are joined by solid-state bonding is indistinct as compared to the boundary between the base layer 190a and the first surface layer 191a that are made of different metals. In general, the boundary between the first surface layer 191a and the bonding layer 151 is almost unrecognizable, or can be barely recognized by small voids or the like created during the solid-state bonding. These points are the same for the other portions joined by solid-state bonding in the present disclosure.

The second surface layer 192a is disposed on the surface of the base layer 190a on the z1 side in the z direction. The second surface layer 192a is joined to the first conductive part 2A by solid-state bonding. In the present embodiment, the second surface layer 192a mainly contains silver (Ag). The thickness of the second surface layer 192a is not particularly limited. In the present embodiment, the second surface layer 192a is thinner than the base layer 190a. The thickness of the second surface layer 192a is at least 0.1 μm and at most 15 μm, for example.

The bonding layer 21A of the first conductive part 2A corresponds to a second bonding layer in the joining structure B11. The bonding layer 21A is disposed on the surface of the body layer 20A on the z2 side in the z direction. The bonding layer 21A is joined to the second surface layer 192a by solid-state bonding. In the present embodiment, the bonding layer 21A mainly contains silver (Ag). The thickness of the bonding layer 21A is not particularly limited, and may be at least 0.1 μm and at most 15 μm.

The main component of each of the second surface layer 192a and the bonding layer 21A is not limited to a particular metal, as long as the metal allows the second surface layer 192a and the bonding layer 21A to be joined by solid-state bonding.

As shown in FIG. 17, the semiconductor device A1 includes a joining structure B12. The joining structure B12 is a structure in which a second switching element 1B as a first bonding target is bonded to the second conductive part 2B as a second bonding target via an intermediate bonding material 19b.

The intermediate bonding material 19b includes a base layer 190b, a first surface layer 191b, and a second surface layer 192b.

The base layer 190b contains copper (Cu) as a main component. The thickness of the base layer 190b is not particularly limited. In the present embodiment, the base layer 190b is thicker than each of the first surface layer 191b and the second surface layer 192b. The thickness of the base layer 190b is at least 50 μm and at most 300 μm, for example.

The first surface layer 191b is disposed on the surface of the base layer 190b on the z2 side in the z direction. The first surface layer 191b is joined to the second switching element 1B by solid-state bonding. In the present embodiment, the first surface layer 191b mainly contains silver (Ag). The thickness of the first surface layer 191b is not particularly limited. In the present embodiment, the first surface layer 191b is thinner than the base layer 190b. The thickness of the first surface layer 191b is at least 0.1 μm and at most 15 μm, for example.

In the present embodiment, the second switching element 1B further includes a bonding layer 151 identical to the bonding layer 151 of the first switching element 1A. The bonding layer 151 of the second switching element 1B is joined to the first surface layer 191b by solid-state bonding.

The main component of each of the first surface layer 191b and the bonding layer 151 is not limited to a particular metal, as long as the metal allows the first surface layer 191b and the bonding layer 151 to be joined by solid-state bonding.

The second surface layer 192b is disposed on the surface of the base layer 190b on the z1 side in the z direction. The second surface layer 192b is joined to the second conductive part 2B by solid-state bonding. In the present embodiment, the second surface layer 192b mainly contains silver (Ag). The thickness of the second surface layer 192b is not particularly limited. In the present embodiment, the second surface layer 192b is thinner than the base layer 190b. The thickness of the second surface layer 192b is at least 0.1 μm and at most 15 μm, for example.

The bonding layer 21B of the second conductive part 2B corresponds to a second bonding layer in the joining structure B12. The bonding layer 21B is disposed on the surface of the body layer 20B on the z2 side in the z direction. The bonding layer 21B is joined to the second surface layer 192b by solid-state bonding. In the present embodiment, the bonding layer 21B mainly contains silver (Ag). The thickness of the bonding layer 21B is not particularly limited, and may be at least 0.1 μm and at most 15 μm.

The main component of each of the second surface layer 192b and the bonding layer 21B is not limited to a particular metal, as long as the metal allows the second surface layer 192b and the bonding layer 21B to be joined by solid-state bonding.

Supporting substrate 3:

The supporting substrate 3 supports the supporting conductor 2. The supporting substrate 3 may be a direct bonded copper (DBC) substrate, for example. In a different example, the supporting substrate 3 may be a direct bonded aluminum (DBA) substrate. The supporting substrate 3 includes an insulating layer 31, a first metal layer 32, and a second metal layer 33.

The insulating layer 31 is made of a ceramic material having high thermal conductivity, for example. Suitable ceramic materials include aluminum nitride (AlN), silicon nitride (SiN), aluminum oxide (Al₂O₃), and zirconia toughened alumina (ZTA). Instead of a ceramic material, the insulating layer 31 may be made of an insulating resin material. In plan view, the insulating layer 31 is rectangular, for example.

The first metal layer 32 is formed on the upper surface (the surface facing the z2 side) of the insulating layer 31. The first metal layer 32 is made of a material containing Cu, for example. In another example, the material of the first metal layer 32 may contain aluminum (Al) instead of Cu. The first metal layer 32 includes a first part 32A and a second part 32B. The first part 32A and the second part 32B are spaced apart from each other in the x direction. The first part 32A is located on the x1 side relative to the second part 32B. The first part 32A is where the first conductive part 2A is bonded and supports the first conductive part 2A. The second part 32B is where the second conductive part 2B is bonded and supports the second conductive part 2B. The first part 32A and the second part 32B are rectangular in plan view, for example.

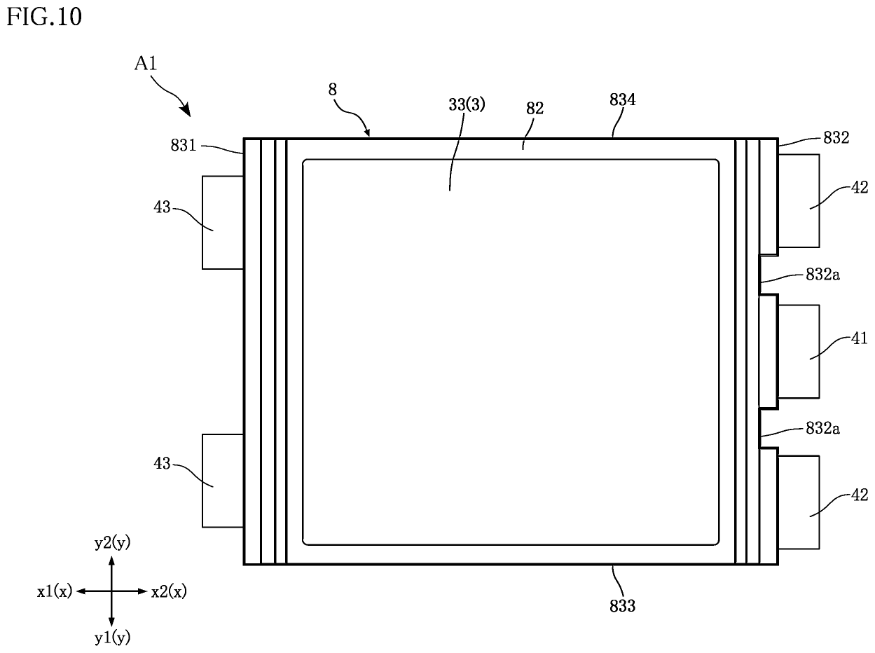

The second metal layer 33 is formed on the lower surface (the surface facing the z1 side) of the insulating layer 31. The second metal layer 33 is made of the same material as the first metal layer 32. As shown in FIGS. 10 to 22, the lower surface (the surface facing the z1 side) of the second metal layer 33 is exposed from the resin member 8. In a different example, the lower surface of the second metal layer 33 may be covered with the resin member 8. In the example in which the lower surface of the second metal layer 33 is exposed from the resin member 8, a non-illustrated heat-dissipating member (e.g., heat sink) may be attached to the exposed lower surface. In plan view, the second metal layer 33 overlaps with both of the first part 32A and the second part 32B.

Joining structures B13 and B14:

As shown in FIG. 15, the semiconductor device A1 includes a joining structure B13. The joining structure B13 is a structure in which a first conductive part 2A as a first bonding target is bonded to the supporting substrate 3 as a second bonding target via the intermediate bonding material 29a.

The intermediate bonding material 29a includes a base layer 290a, a first surface layer 291a, and a second surface layer 292a.

The base layer 290a contains copper (Cu) as a main component. The thickness of the base layer 290a is not particularly limited. In the present embodiment, the base layer 290a is thicker than each of the first surface layer 291a and the second surface layer 292a. The thickness of the base layer 290a is at least 50 μm and at most 300 μm, for example.

The first surface layer 291a is disposed on the surface of the base layer 290a on the z2 side in the z direction. The first surface layer 291a is joined to the first conductive part 2A by solid-state bonding. In the present embodiment, the first surface layer 291a mainly contains silver (Ag). The thickness of the first surface layer 291a is not particularly limited. In the present embodiment, the first surface layer 291a is thinner than the base layer 290a. The thickness of the first surface layer 291a is at least 0.1 μm and at most 15 μm, for example.

The bonding layer 22A of the first conductive part 2A corresponds to a first bonding layer in the joining structure B13. The bonding layer 22A is disposed on the surface of the body layer 20A on the z1 side in the z direction. The bonding layer 22A is joined to the first surface layer 291a by solid-state bonding. In the present embodiment, the bonding layer 22A mainly contains silver (Ag). The thickness of the bonding layer 22A is not particularly limited, and may be at least 0.1 μm and at most 15 μm.

The main component of each of the first surface layer 291a and the bonding layer 22A is not limited to a particular metal, as long as the metal allows the first surface layer 291a and the bonding layer 22A to be joined by solid-state bonding.

The second surface layer 292a is disposed on the surface of the base layer 290a on the z1 side in the z direction. The second surface layer 292a is joined to the supporting substrate 3 by solid-state bonding. In the present embodiment, the second surface layer 292a mainly contains silver (Ag). The thickness of the second surface layer 292a is not particularly limited. In the present embodiment, the second surface layer 292a is thinner than the base layer 290a. The thickness of the second surface layer 292a is at least 0.1 μm and at most 15 μm, for example.

The supporting substrate 3 of the present embodiment further includes a bonding layer 321A. The bonding layer 321A corresponds to a second bonding layer in the joining structure B13. The bonding layer 321A is disposed on the surface of the first part 32A on the z2 side in the z direction. The bonding layer 321A is joined to the second surface layer 292a by solid-state bonding. In the present embodiment, the bonding layer 321A mainly contains silver (Ag). The thickness of the bonding layer 321A is not particularly limited, and may be at least 0.1 μm and at most 15 μm.

The main component of each of the second surface layer 292a and the bonding layer 321A is not limited to a particular metal, as long as the metal allows the second surface layer 292a and the bonding layer 321A to be joined by solid-state bonding.

As shown in FIG. 18, the semiconductor device A1 includes a joining structure B14. The joining structure B14 is a structure in which the second conductive part 2B as a first bonding target is bonded to the supporting substrate 3 as a second bonding target via the intermediate bonding material 29b.

The intermediate bonding material 29b includes a base layer 290b, a first surface layer 291b, and a second surface layer 292b.

The base layer 290b contains copper (Cu) as a main component. The thickness of the base layer 290b is not particularly limited. In the present embodiment, the base layer 290b is thicker than each of the first surface layer 291b and the second surface layer 292b. The thickness of the base layer 290b is at least 50 μm and at most 300 μm, for example.

The first surface layer 291b is disposed on the surface of the base layer 290b on the z2 side in the z direction. The first surface layer 291b is joined to the second conductive part 2B by solid-state bonding. In the present embodiment, the first surface layer 291b mainly contains silver (Ag). The thickness of the first surface layer 291b is not particularly limited. In the present embodiment, the first surface layer 291b is thinner than the base layer 290b. The thickness of the first surface layer 291b is at least 0.1 μm and at most 15 μm, for example.

The bonding layer 22B of the second conductive part 2B corresponds to a first bonding layer in the joining structure B14. The bonding layer 22B is disposed on the surface of the body layer 20B on the z1 side in the z direction. The bonding layer 22B is joined to the first surface layer 291b by solid-state bonding. In the present embodiment, the bonding layer 22B mainly contains silver (Ag). The thickness of the bonding layer 22B is not particularly limited, and may be at least 0.1 μm and at most 15 μm.

The main component of each of the first surface layer 291b and the bonding layer 22B is not limited to a particular metal, as long as the metal allows the first surface layer 291b and the bonding layer 22B to be joined by solid-state bonding.

The second surface layer 292b is disposed on the surface of the base layer 290b on the z1 side in the z direction. The second surface layer 292b is joined to the supporting substrate 3 by solid-state bonding. In the present embodiment, the second surface layer 292b mainly contains silver (Ag). The thickness of the second surface layer 292b is not particularly limited. In the present embodiment, the second surface layer 292b is thinner than the base layer 290b. The thickness of the second surface layer 292b is at least 0.1 μm and at most 15 μm, for example.

The supporting substrate 3 of the present embodiment further includes a bonding layer 321B. The bonding layer 321B corresponds to a second bonding layer in the joining structure B14. The bonding layer 321B is disposed on the surface of the second part 32B on the z2 side in the z direction. The bonding layer 321B is joined to the second surface layer 292b by solid-state bonding. In the present embodiment, the bonding layer 321B mainly contains silver (Ag). The thickness of the bonding layer 321B is not particularly limited, and may be at least 0.1 μm and at most 15 μm.

The main component of each of the second surface layer 292b and the bonding layer 321B is not limited to a particular metal, as long as the metal allows the second surface layer 292b and the bonding layer 321B to be joined by solid-state bonding.

Power terminals 41 to 43:

Each of the power terminals 41 to 43 is made of a metal plate. The metal plate contains Cu or a Cu alloy, for example. In the example shown in FIGS. 1 to 5, 8, and 10, the semiconductor device A1 includes one power terminal 41, two power terminals 42 and two power terminals 43.

The first power supply voltage mentioned above is applied between the power terminal 41 and each of the two power terminals 42. The power terminal 41 is a terminal (P terminal) connected to the positive electrode of a DC power source, and each of the two power terminals 42 is a terminal (N terminal) connected to the negative electrode of the DC power source. In a different example, the power terminal 41 may be an N terminal, and the two power terminals 42 may be P terminals. In such a case, the wiring within the package may be also changed according to the respective polarities of the terminals. The second power supply voltage mentioned above is applied to each of the two power terminal 43. Each of the power terminals 43 is an output terminal for outputting the voltage (the second power supply voltage mentioned above) resulting from the conversion through the switching operations of the first switching elements 1A and the second switching elements 1B. Each of the power terminals 41 to 43 includes a portion covered with the resin member 8 and a portion exposed from the resin member 8.

As shown in FIGS. 8, 12, and 19, the power terminal 41 is formed integrally with the first conductive part 2A. In a different example, the power terminal 41 may be a separate component that is electrically bonded to the first conductive part 2A. As shown in FIG. 8, the power terminal 41 is offset toward the x2 side from the semiconductor elements 1 and the first conductive part 2A (the supporting conductor 2). The insulating layer 31 is electrically connected to the first conductive part 2A and hence to the reverse-surface electrodes 15 (the drain electrodes) of the first switching elements 1A via the first conductive part 2A. The power terminal 41 is an example of a “first power terminal”.

As shown in FIGS. 8 and 11, for example, the two power terminals 42 are spaced apart from the first conductive part 2A. The two power terminals 42 are bonded to the second conductive member 72. As shown in FIG. 8, the two power terminals 42 are offset toward the x2 side from the semiconductor elements 1 and the first conductive part 2A (the supporting conductor 2). The two power terminals 42 are electrically connected to the second conductive member 72, and hence to the second obverse-surface electrodes 12 (the source electrodes) of the second switching elements 1B via the second conductive member 72. Each power terminal 42 is an example of a “second power terminal”.

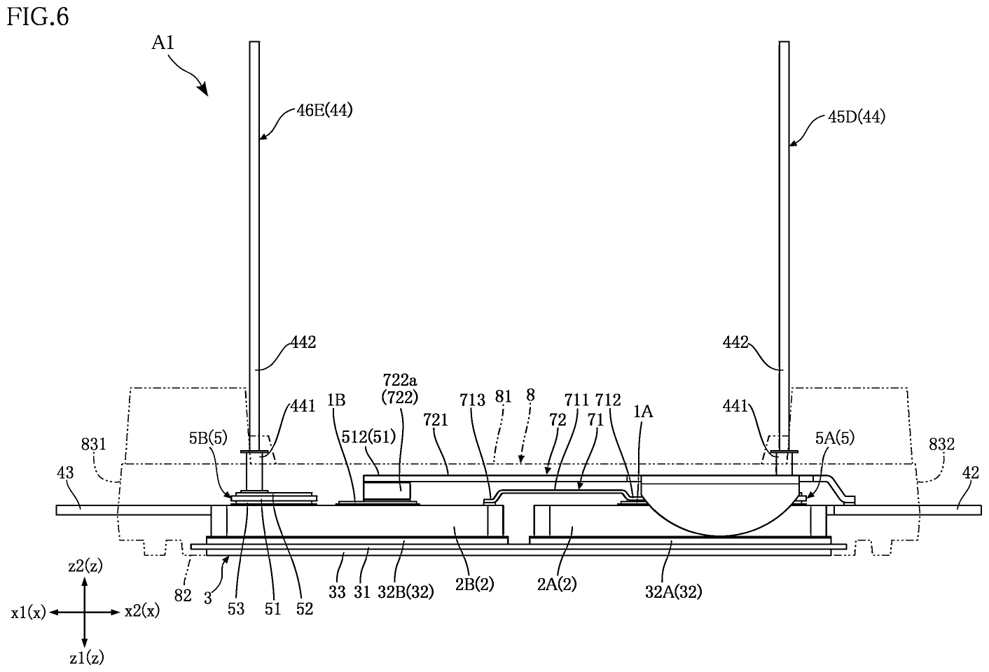

Each of the power terminals 41 and 42 protrudes from the resin member 8 toward the x2 side. The power terminals 41 and 42 are spaced apart from each other. The two power terminals 42 are located opposite to each other across the power terminal 41 in the y direction. As can be seen from FIGS. 6, 7, and 9, the power terminal 41 and the two power terminals 42 overlap with each other as viewed in the y direction.

As shown in FIGS. 8 and 11, the two power terminals 43 are integrally formed with the second conductive part 2B, for example. In a different example, each of the power terminals 43 may be a separate component that is electrically bonded to the second conductive part 2B. As shown in FIG. 8, the two power terminals 43 are offset toward the x1 side from the semiconductor elements 1 and the second conductive part 2B (the supporting conductor 2). The two power terminals 43 are electrically connected to the second conductive part 2B and hence to the reverse-surface electrodes 15 (the drain electrodes) of the second switching elements 1B via the second conductive part 2B. Note that the number of power terminals 43 is not limited to two, and one or three or more power terminals 43 may be provided. When one power terminal 43 is provided, the power terminal 43 is preferably connected to the central portion of the second conductive part 2B in the y direction. Each power terminal 43 is an example of a “third power terminal”. Control terminals 44:

The control terminals 44 are pin-like terminals for controlling the drive of the semiconductor elements 1 (the first switching elements 1A and the second switching elements 1B). The control terminals 44 may be press-fit terminals, for example. Each control terminal 44 may have a dimension of at least 10 mm and at most 30 mm (in one example, a dimension of 15.8 mm) in the z direction. The dimension of a control terminal 44 in the z direction refers to the dimension from the lower end (the end on the z1 side) of a holder 441 described below to the upper end (the end in the z2 side) of a metal pin 442 described below. As shown in FIGS. 1 and 4, the control terminals 44 include the first control terminals 45 and the second control terminals 46. The first control terminals 45 are used to control the first switching elements 1A. The second control terminals 46 are used to control the second switching elements 1B.

First control terminals 45:

As shown in FIG. 4, the first control terminals 45 are spaced apart from each other in the y direction. The first control terminals 45 are secured to the signal substrate 5 (the first signal substrate 5A). As shown in FIGS. 5 to 7, and 12, the first control terminals 45 are located between the plurality of first switching elements 1A and the plurality of power terminals 41 and 42 in the x direction. As shown in FIGS. 1 and 4, the first control terminals 45 include a first drive terminal 45A and a plurality of first sensing terminals 45B to 45E.

The first drive terminal 45A is a terminal (a gate terminal) used to input a drive signal to the first switching elements 1A. A first drive signal for driving the first switching elements 1A is inputted (for example, a gate voltage is applied) to the first drive terminal 45A.

The first sensing terminal 45B is a terminal (a source sense terminal) used to detect a source signal of the first switching elements 1A. The first sensing terminal 45B outputs a first detection signal that is used to detect the conducting state of the first switching elements 1A. For example, the voltage applied to the second obverse-surface electrodes 12 (the source electrodes) of the first switching elements 1A (the voltage corresponding to the source current) is detected as the first detection signal at the first sensing terminal 45B.

The first sensing terminal 45C and the first sensing terminal 45D are both electrically connected to one of the two thermistors 17. The thermistor 17 is the one mounted on the first signal substrate 5A, which will be described below.

The first sensing terminal 45E is a terminal (a drain sense terminal) used to detect a drain signal of the first switching elements 1A. The voltage applied to the reverse-surface electrodes 15 (the drain electrodes) of the first switching elements 1A (the voltage corresponding to the drain current) is detected at the first sensing terminal 45E.

Second control terminals 46:

As shown in FIG. 4, the second control terminals 46 are spaced apart from each other in the y direction. The second control terminals 46 are secured to the signal substrate 5 (the second signal substrate 5B). As shown in FIGS. 5 to 7, and 12, the second control terminals 46 are located between the plurality of second switching elements 1B and the plurality of power terminals 43 in the x direction. As shown in FIGS. 1 and 4, the second control terminals 46 include a second drive terminal 46A and a plurality of second sensing terminals 46B to 46E.

The second drive terminal 46A is a terminal (a gate terminal) used to input a drive signal to the second switching elements 1B. A second drive signal for driving the second switching elements 1B is inputted (for example, a gate voltage is applied) to the second drive terminal 46A.

The second sensing terminal 46B is a terminal (a source sense terminal) used to detect a source signal of the second switching elements 1B. The second sensing terminal 46B outputs a second detection signal that is used to detect the conducting state of the second switching elements 1B. For example, the voltage applied to the second obverse-surface electrodes 12 (the source electrodes) of the second switching elements 1B (the voltage corresponding to the source current) is detected as the second detection signal at the second sensing terminal 46B.

The second sensing terminals 46C and 46D are both electrically connected to one of the two thermistors 17. The thermistor 17 is the one mounted on the second signal substrate 5B, which will be described below.

The second sensing terminal 46E is a terminal (a drain sense terminal) used to detect a drain signal of the second switching elements 1B. The voltage applied to the reverse-surface electrodes 15 (the drain electrodes) of the second switching elements 1B (the voltage corresponding to the drain current) is detected at the second sensing terminal 46E.

### Control Terminals 44:

Each of the control terminals 44 (the first control terminals 45 and the second control terminals 46) includes a holder 441 and a metal pin 442.

The holder 441 is made of a conductive material. As shown in FIGS. 13 and 16, the holder 441 is bonded to the signal substrate 5 (a first metal layer 52 described below) via a conductive bonding material 449. The holder 441 includes a tubular part, an upper flange, and a lower flange. The upper flange is connected to the upper end (the end on the z2 side) of the tubular part in the z direction, and the lower flange is connected to the lower end of the tubular part in the z direction (the end on the z1 side). The metal pin 442 is inserted into the holder 441 to extend at least from the upper flange to the tubular part. The holder 441 is embedded in the resin member 8.

The metal pin 442 is a rod-like member extending in the z direction. The metal pin 442 is press-fitted into the holder 441 and supported by the holder 441. The metal pin 442 is electrically connected to the signal substrate 5 (the first metal layer 52 described below) at least via the holder 441. As shown in FIGS. 13 and 16, the metal pin 442 inserted into the holder 441 may have the lower end (the end on the z1 side) in contact with the conductive bonding material 449, in which case, the metal pin 442 is electrically connected to the signal substrate 5 also via the conductive bonding material 449.

Signal substrate 5:

The signal substrate 5 supports the control terminals 44. In the z direction, the signal substrate 5 is interposed between the supporting conductor 2 and the plurality of control terminals 44. The signal substrate 5 has a thickness (a dimension in the thickness direction z) of at least 0.5 mm and at most 1.0 mm, for example. The dimension of each control terminal 44 in the thickness direction z is at least 20 times and at most 30 times the thickness (the dimension in the thickness direction z) of the signal substrate 5. The signal substrate 5 includes the first signal substrate 5A and the second signal substrate 5B.

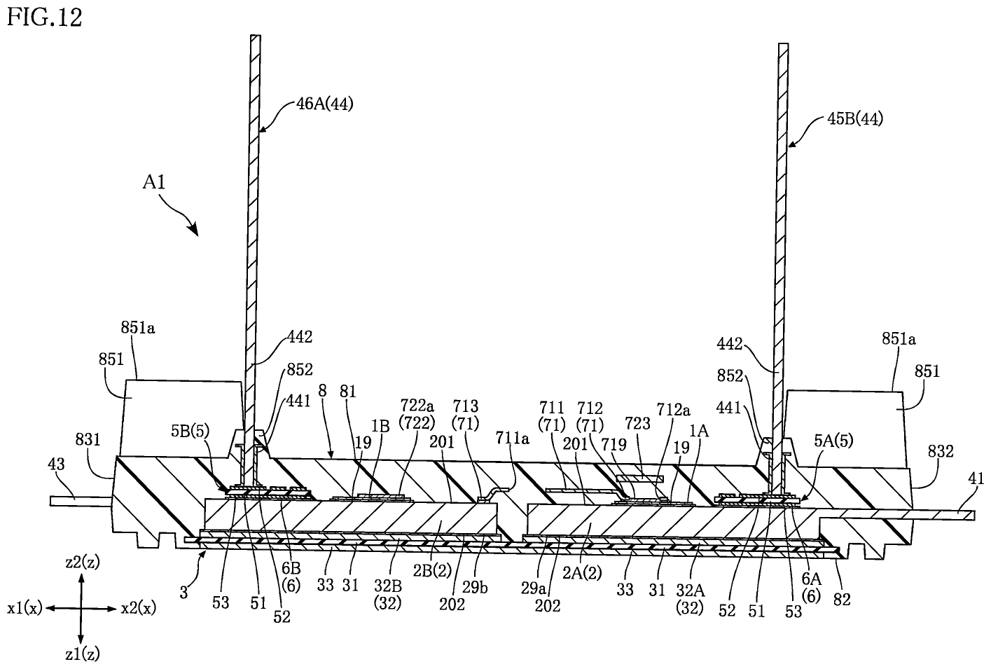

As shown in FIGS. 5, 12, and 13, the first signal substrate 5A is disposed on the first conductive part 2A, and supports the first control terminals 45. As shown in FIGS. 12, 13, and 19, the first signal substrate 5A is bonded to the first conductive part 2A via the adhesive layer 6 (the first adhesive body 6A).

As shown in FIGS. 5, 12, and 16, the second signal substrate 5B is disposed on the second conductive part 2B, and supports the second control terminals 46. As shown in FIGS. 12, 16, and 19, the second signal substrate 5B is bonded to the second conductive part 2B via the adhesive layer 6 (the second adhesive body 6B).

The signal substrate 5 (each of the first signal substrate 5A and the second signal substrate 5B) may be a DBC substrate, for example. The signal substrate 5 is a stack of an insulating substrate 51, a first metal layer 52, and a second metal layer 53. Unless otherwise specifically noted, the description of the insulating substrate 51, the first metal layer 52, and the second metal layer 53 given below commonly applies to the first signal substrate 5A and the second signal substrate 5B.

The insulating substrate 51 is made of a ceramic material, for example. Suitable ceramic materials include AlN, SiN and Al₂O₃. The insulating substrate 51 may be rectangular in plan view. As shown in FIGS. 13 and 16, the insulating substrate 51 has an obverse surface 51a and a reverse surface 51b. The obverse surface 51a and the reverse surface 51b are spaced apart from each other in the z direction. The obverse surface 51a faces the z2 side, and the reverse surface 51b faces the z1 side. The reverse surface 51b faces the supporting conductor 2.

As shown in FIGS. 13 and 16, the second metal layer 53 is formed on the reverse surface 51b of the insulating substrate 51. The second metal layer 53 is bonded to the supporting conductor 2 via the adhesive layer 6. The second metal layer 53 of the first signal substrate 5A is bonded to the first conductive part 2A via the first adhesive body 6A described below. The second metal layer 53 of the second signal substrate 5B is bonded to the second conductive part 2B via the second adhesive body 6B described below. The second metal layer 53 is made of Cu or a Cu alloy, for example. The second metal layer 53 is an example of a “metal layer”.

As shown in FIGS. 13 and 16, the first metal layer 52 is formed on the obverse surface 51a of the insulating substrate 51. Each of the control terminals 44 is disposed to stand on the first metal layer 52. The first control terminals 45 are disposed to stand on the first metal layer 52 of the first signal substrate 5A, and the second control terminals 46 are disposed to stand on the first metal layer 52 of the second signal substrate 5B. The first metal layer 52 is made of Cu or a Cu alloy, for example. As shown in FIG. 8, the first metal layer 52 includes a plurality of wiring layers 521 to 526. The wiring layers 521 to 526 are spaced apart and insulated from each other.

As shown in FIG. 8, a plurality of wires 73 are bonded to the wiring layer 521, each wire 73 electrically connecting the wiring layer 521 to the first obverse-surface electrode 11 (the gate electrode) of a semiconductor element 1. The wiring layer 521 of the first signal substrate 5A is electrically connected to the first obverse-surface electrodes 11 of the first switching elements 1A via the relevant wires 73. The wiring layer 521 of the second signal substrate 5B is electrically connected to the first obverse-surface electrodes 11 of the second switching elements 1B via the relevant wires 73.

As shown in FIG. 8, a plurality of wires 75 are bonded to the wiring layer 526, each wire 75 electrically connecting the wiring layer 526 to the wiring layer 521. The wiring layer 526 of the first signal substrate 5A is electrically connected to the first obverse-surface electrodes 11 (the gate electrodes) of the first switching elements 1A via the relevant wires 75, the wiring layer 521 of the first signal substrate 5A, and the relevant wires 73. The wiring layer 526 of the second signal substrate 5B is electrically connected to the first obverse-surface electrodes 11 (the gate electrodes) of the second switching elements 1B via the relevant wires 75, the wiring layer 521 of the second signal substrate 5B, and the relevant wires 73. The first drive terminal 45A is bonded to the wiring layer 526 of the first signal substrate 5A, and the second drive terminal 46A is bonded to the wiring layer 526 of the second signal substrate 5B.

As shown in FIG. 8, a plurality of wires 74 are bonded to the wiring layer 522, each wire 74 electrically connecting the wiring layer 522 to the third obverse-surface electrode 13 (the source-sense electrode) of a semiconductor element 1. The wiring layer 522 of the first signal substrate 5A is electrically connected to the third obverse-surface electrodes 13 (the source-sense electrodes) of the first switching elements 1A via the relevant wires 74. The wiring layer 522 of the second signal substrate 5B is electrically connected to the third obverse-surface electrodes 13 (the source-sense electrodes) of the second switching elements 1B via the relevant wires 74. The first sensing terminal 45B is bonded to the wiring layer 522 of the first signal substrate 5A, and the second sensing terminal 46B is bonded to the wiring layer 522 of the second signal substrate 5B.

As shown in FIG. 8, the thermistors 17 are bonded to the wiring layers 523 and 524. As shown in FIG. 8, the first sensing terminals 45C and 45D are bonded respectively to the wiring layers 523 and 524 of the first signal substrate 5A. The second sensing terminals 46C and 46D are bonded respectively to the wiring layers 523 and 524 of the second signal substrate 5B.

A wire 76 is bonded to the wiring layer 525, the wire 76 electrically connecting the wiring layer 525 to the supporting conductor 2. As shown in FIG. 8, the wiring layer 525 of the first signal substrate 5A is electrically connected to the first conductive part 2A via the relevant wire 76. The wiring layer 525 of the second signal substrate 5B is electrically connected to the second conductive part 2B via the relevant wire 76. The first sensing terminal 45E is bonded to the wiring layer 525 of the first signal substrate 5A. The second sensing terminal 46E is bonded to the wiring layer 525 of the second signal substrate 5B.

The signal substrate 5 is not limited to a DBC substrate, and may be a printed board such as a glass epoxy board instead. The printed board includes at least the wiring layers 521 to 526. Adhesive layer 6:

The adhesive layer 6 bonds the signal substrate 5 and the supporting conductor 2. In the z direction, the adhesive layer 6 is interposed between the signal substrate 5 and the supporting conductor 2. The adhesive layer 6 overlaps with the signal substrate 5 in plan view. The adhesive layer 6 has a thickness (a dimension in the z direction) of at least 20 μm and at most 200 μm (in one example, a thickness of 85 μm).

As shown in FIGS. 12 to 16, the adhesive layer 6 includes the first adhesive body 6A and the second adhesive body 6B. The first adhesive body 6A bonds the first signal substrate 5A and the first conductive part 2A. The first adhesive body 6A is interposed between the first signal substrate 5A and the first conductive part 2A, and overlaps with the first signal substrate 5A in plan view. The second adhesive body 6B bonds the second signal substrate 5B and the second conductive part 2B. The second adhesive body 6B is interposed between the second signal substrate 5B and the second conductive part 2B, and overlaps with the second signal substrate 5B in plan view.

As shown in FIGS. 13 and 16, the adhesive layer 6 (each of the first adhesive body 6A and the second adhesive body 6B) includes an insulating layer 61 and a pair of adhesive layers 62 and 63. Unless otherwise specifically noted, the description of the insulating layer 61 and the adhesive layers 62 and 63 given below commonly applies to the first adhesive body 6A and the second adhesive body 6B.

The insulating layer 61 is made of a resin material. In view of the heat resistance and electrical insulation, polyimide is a desirable example of the resin material. The insulating layer 61 of the first adhesive body 6A electrically insulates the first signal substrate 5A and the first conductive part 2A. Similarly, the insulating layer 61 of the second adhesive body 6B electrically insulates the second signal substrate 5B and the second conductive part 2B. In one example, the insulating layer 61 is in the form of a film. In another example, the insulating layer 61 may be in the form of a sheet or a plate. In the present disclosure, the sheet refers to a piece of material that is as flexible as the film but thicker than the film. Also, the plate refers to a piece of material that is harder and less flexible than the film or the sheet and thicker than the sheet. The definitions of the film, sheet, and plate are not limited to those described above and may be adapted according to common classifications. The insulating layer 61 has a thickness (a dimension in the thickness direction z) that is at least 0.1% and at most 1.0% of the dimension of each control terminal 44 in the thickness direction z. The insulating layer 61 has a thickness (a dimension in the thickness direction z) that is at least 20% and at most 75% of the thickness (the dimension in the thickness direction z) of the adhesive layer 6. Specifically, the thickness (the dimension in the thickness direction z) of the insulating layer 61 is at least 10 μm and at most 150 μm (in one example, the thickness is 25 μm).

As shown in FIGS. 13 and 16, the insulating layer 61 has an obverse surface 61a and a reverse surface 61b. The obverse surface 61a and the reverse surface 61b are spaced apart from each other in the z direction. The obverse surface 61a faces the z2 side (upward in the z direction), and the reverse surface 61b faces the z1 side (downward in the z direction).

The adhesive layers 62 and 63 are disposed on the respective sides of the insulating layer 61 in the z direction. The adhesive layers 62 and 63 are made of a silicone-based adhesive or an acrylic-based adhesive, for example. Each of the adhesive layers 62 and 63 has a thickness (a dimension in the thickness direction z) that is at least 10% and at most 150% of the thickness (the dimension in the thickness direction z) of the insulating layer 61. Specifically, the thickness (the dimension in the thickness direction z) of each of the adhesive layers 62 and 63 is at least 5 μm and at most 50 μm (in one example, the thickness is 30 μm).

As shown in FIGS. 13 and 16, the adhesive layer 62 is formed on the obverse surface 61a. In the z direction, the adhesive layer 62 is interposed between the insulating layer 61 and the signal substrate 5. The adhesive layer 62 of the first adhesive body 6A is interposed between the insulating layer 61 of the first adhesive body 6A and the first signal substrate 5A in the z direction. The adhesive layer 62 of the second adhesive body 6B is located between the insulating layer 61 of the second adhesive body 6B and the second signal substrate 5B in the z direction.

As shown in FIGS. 13 and 16, the adhesive layer 63 is formed on the reverse surface 61b. In the z direction, the adhesive layer 63 is interposed between the insulating layer 61 and the supporting conductor 2. The adhesive layer 63 of the first adhesive body 6A is interposed between the insulating layer 61 of the first adhesive body 6A and the first conductive part 2A in the z direction. The adhesive layer 63 of the second adhesive body 6B is interposed between the insulating layer 61 of the second adhesive body 6B and the second conductive part 2B in the z direction.

As can be understood from the above description, the adhesive layer 6 of the present disclosure is a kind of double-sided adhesive tape. In a process of manufacturing the semiconductor device A1, the adhesive layer 6 may be attached first to the signal substrate 5 to which the control terminals 44 have been bonded, and then to the supporting conductor 2. An example of the adhesive layer 6 is not limited to a double-sided adhesive tape, but excludes a material, such as solder, that is melted to bond two members together. In other words, the adhesive layer 6 is a material capable of bonding two members together without being melted.

### First Conductive Member 71 and Second Conductive Member 72:

The first conductive member 71 and the second conductive member 72, together with the supporting conductor 2, form paths for the main circuit current that is switched on and off by the semiconductor elements 1 (the first switching elements 1A and the second switching elements 1B). The first conductive member 71 and the second conductive member 72 are spaced apart from the respective obverse surfaces 201 of the first conductive part 2A and the second conductive part 2B toward the z2 side, and overlap with the respective obverse surfaces 201 in plan view. The first conductive member 71 and the second conductive member 72 are constructed of metal plates, for example. The metal is Cu or a Cu alloy, for example. The first conductive member 71 and the second conductive member 72 have been bent as necessary.

The first conductive member 71 electrically connects the first switching elements 1A and the second conductive part 2B. As shown in FIGS. 5 and 8, the first conductive member 71 is connected to the second obverse-surface electrodes 12 (the source electrodes) of the first switching elements 1A and also to the second conductive part 2B, thereby electrically connecting the second obverse-surface electrodes 12 of the first switching elements 1A and the second conductive part 2B. The first conductive member 71 forms paths for the main circuit current that is switched on and off by the first switching elements 1A. As shown in FIGS. 5, 8, and 12, the first conductive member 71 includes a main part 711, a plurality of first connecting ends 712 and a plurality of second connecting ends 713.

The main part 711 is located between the plurality of first switching elements 1A and the second conductive part 2B in the x direction. The main part 711 has a band shape extending in the y direction. As shown in FIG. 12, the main part 711 is located farther toward the z2 side than the first connecting ends 712 and the second connecting ends 713. As shown in FIGS. 5, 8, and 12, in the present embodiment, the main part 711 is formed with a plurality of openings 711a. Each of the openings 711a is a through-hole penetrating the first conductive member 71 (the main part 711) in the z direction. The openings 711a are aligned at intervals in the y direction. In plan view, the openings 711a do not overlap with the second conductive member 72. The openings 711a are provided to improve the flow of a melted resin material injected in the process of forming the resin member 8. That is, the openings 711a allow the flow of the resin material between the upper region (on the z2 side) and the lower region (on the z1 side) around the main part 711 (the first conductive member 71). The shape of the main part 711 is not limited to this configuration and may be formed without any opening 711a.

The first connecting ends 712 and the second connecting ends 713 are connected to the main part 711, and each of the first connecting ends 712 and the second connecting ends 713 is located at a position opposite a first switching element 1A. As shown in FIG. 12, the first connecting ends 712 are bonded to the second obverse-surface electrodes 12 of the first switching elements 1A via a conductive bonding material 719. The second connecting ends 713 are bonded to the second conductive part 2B via the conductive bonding material 719. Examples of the conductive bonding material 719 include solder, a metal paste, and sintered metal. In the example shown in FIGS. 8, 12, 13, and 21, each of the first connecting ends 712 is formed with an opening 712a. Preferably, each opening 712a is formed to overlap with the central portion of a first switching element 1A in plan view. As shown in FIGS. 12, 13, and 21, each opening 712a is a through-hole penetrating the relevant first connecting end 712 in the z direction. The openings 712a are used to position the first conductive member 71 relative to the supporting conductor 2.

In the illustrated example, the main part 711 connects the first connecting ends 712 and the second connecting ends 713. In another example, the main part 711 may be composed of a plurality of separate portions each connecting a first connecting end 712 and a second connecting end 713. In other words, a separate first conductive member 71 may be provided for each first switching element 1A.

As shown in FIG. 5, the second conductive member 72 is connected to the second obverse-surface electrodes 12 (the source electrodes) of the second switching elements 1B and the power terminals 42, thereby electrically connecting the second obverse-surface electrodes 12 of the second switching elements 1B to the power terminals 42. The second conductive member 72 forms paths for the main circuit current that is switched on and off by the second switching elements 1B. For example, the second conductive member 72 has a maximum dimension of at least 25 mm and at most 40 mm in the x direction and a maximum dimension of at least 30 mm and at most 45 mm in the y direction. As shown in FIG. 5, the second conductive member 72 includes a pair of first wiring parts 721, a second wiring part 722, a third wiring part 723, and a fourth wiring part 724.

One of the first wiring parts 721 is connected to one of the power terminals 42, and the other first wiring part 721 is connected to the other power terminal 42. As shown in FIG. 5, each of the first wiring parts 721 has a band shape extending in the x direction in plan view. The first wiring parts 721 are spaced apart from each other in the y direction and parallel (or substantially parallel) to each other. As shown in FIGS. 5 and 11, each first wiring part 721 includes a first end 721a. The first end 721a is the end of the first wiring part 721 on the x2 side. As shown in FIG. 11, the first end 721a is offset toward the z1 side from the rest of the first wiring part 721. As shown in FIG. 11, each of the first ends 721a is bonded to one of the power terminals 42 via a conductive bonding material 729. Examples of the conductive bonding material 729 include solder, a metal paste, and sintered metal. In the example shown in FIG. 5, each of the first wiring parts 721 is formed with a plurality of notches. The notches formed in the first wiring part 721 are semicircular in plan view and overlap with the supporting conductor 2 in plan view.

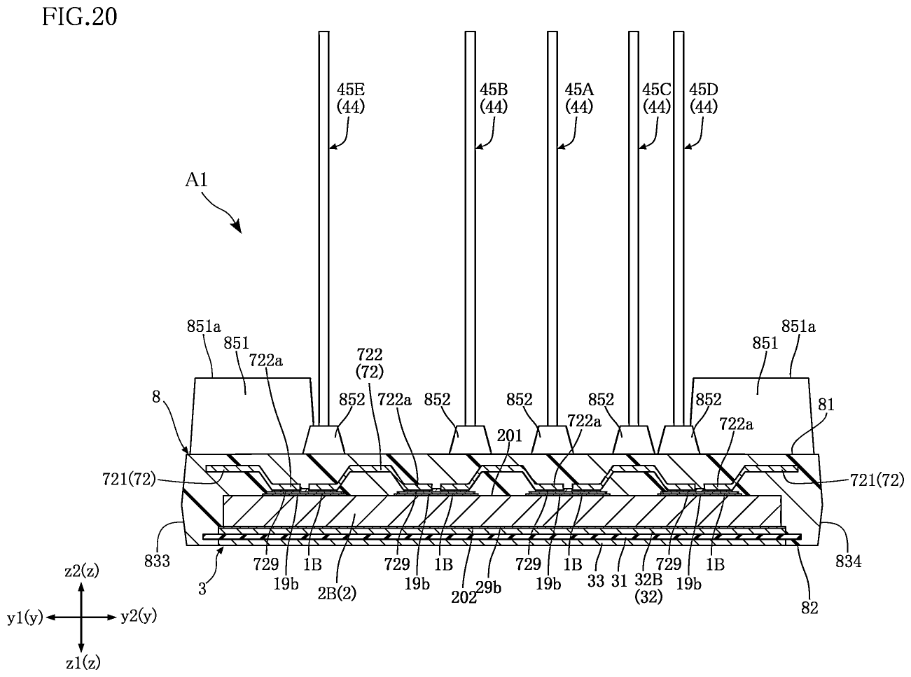

As shown in FIG. 5, the second wiring part 722 is connected to both of the first wiring parts 721. The second wiring part 722 is located between the first wiring parts 721 in the y direction. In plan view, the second wiring part 722 has a band shape extending in the y direction. As shown in FIG. 5, the second wiring part 722 overlaps with the second switching elements 1B. The second wiring part 722 is connected to the second switching elements 1B. The second wiring part 722 has a plurality of recessed regions 722a. As shown in FIG. 20, each of the recessed regions 722a is recessed downward in the z direction (to the z1 side) from the rest of the second wiring part 722. As shown in FIG. 20, the recessed regions 722a of the second wiring part 722 are bonded to the second obverse-surface electrodes 12 (the source electrodes) of the second switching elements 1B via a conductive bonding material 729. In the example shown in FIGS. 5 and 20, each of the recessed regions 722a has a slit. The slit extends in the x direction at the center of the recessed region 722a in the y direction. That is, each recessed region 722a is composed of two sections that are spaced apart from each other in the y direction across the slit. In another example, each recessed region 722a may be formed without a slit.

As shown in FIG. 5, the third wiring part 723 is connected to both of the first wiring parts 721. The third wiring part 723 is located between the first wiring parts 721 in the y direction. In plan view, the third wiring part 723 has a band shape extending in the y direction. The third wiring part 723 is spaced apart from the second wiring part 722 in the x direction. The third wiring part 723 is arranged parallel (or substantially parallel) to the second wiring part 722. As shown in FIG. 5, the third wiring part 723 overlaps with the first switching elements 1A in plan view. In the z direction, the third wiring part 723 is located above (on the z2 side from) the first connecting ends 712 of the first conductive member 71. In plan view, the third wiring part 723 overlaps with the first connecting ends 712.

As shown in FIG. 5, each fourth wiring part 724 is connected to both the second wiring part 722 and the third wiring part 723. The fourth wiring parts 724 are located between the second wiring part 722 and the third wiring part 723 in the x direction. In plan view, each of the fourth wiring parts 724 has a band shape extending in the x direction. The fourth wiring parts 724 are spaced apart from each other in the y direction, and are arranged parallel (or substantially parallel) to each other in plan view. The fourth wiring parts 724 are also parallel (or substantially parallel) to the pair of first wiring parts 721. One end of each fourth wiring part 724 in the x direction is connected to a portion of the third wiring part 723 that is located between two adjacent first switching elements 1A in the y direction in plan view. The other end of each fourth wiring part 724 in the x direction is connected to a portion of the second wiring part 722 that is located between two adjacent second switching elements 1B in the y direction in plan view. In one example, the fourth wiring parts 724 overlap with the first conductive member 71 (the main part 711).

### Wires 73 to 76:

The wires 73 to 76 are bonding wires, for example, and electrically connect two separate parts. The wires 73 to 76 are made of a material containing gold (Au), Al, or Cu.

Each wire 73 is bonded to the wiring layer 521 and the first obverse-surface electrode 11 (the gate electrode) of a semiconductor element 1 to provide an electrical connection between them. As shown in FIG. 8, the wires 73 include those bonded to the wiring layer 521 of the first signal substrate 5A and the first obverse-surface electrodes 11 of the first switching elements 1A, and those bonded to the wiring layer 521 of the second signal substrate 5B and the first obverse-surface electrodes 11 of the second switching elements 1B.

Each wire 74 is bonded to the wiring layer 522 and the third obverse-surface electrode 13 (the source-sense electrode) of a semiconductor element 1 to provide an electrical connection between them. As shown in FIG. 8, the wires 74 include those bonded to the wiring layer 522 of the first signal substrate 5A and the third obverse-surface electrodes 13 of the first switching elements 1A, and those bonded to the wiring layer 522 of the second signal substrate 5B and the third obverse-surface electrodes 13 of the second switching elements 1B. In some configuration, the semiconductor elements 1 are not provided with the third obverse-surface electrodes 13, in which case, the wires 74 are bonded to the second obverse-surface electrodes 12 instead of the third obverse-surface electrodes 13.

The wires 75 are bonded to the wiring layer 521 and the wiring layer 526 to provide an electrical connection between them. As shown in FIG. 8, the wires 75 include those bonded to the wiring layer 521 of the first signal substrate 5A and the wiring layer 526 of the first signal substrate 5A and those bonded to the wiring layer 521 of the second signal substrate 5B and the wiring layer 526 of the second signal substrate 5B.

The wires 76 are bonded to the wiring layer 525 and the supporting conductor 2 to provide an electrical connection between them. As shown in FIG. 8, the wires 76 include one bonded to the wiring layer 525 of the first signal substrate 5A and the first conductive part 2A and one bonded to the wiring layer 525 of the second signal substrate 5B and the second conductive part 2B.

Resin member 8:
The resin member 8 is a sealing material for protecting the semiconductor elements 1 (the first switching elements 1A and the second switching elements 1B). The resin member 8 covers the semiconductor elements 1 (the first switching elements 1A and the second switching elements 1B), the supporting conductor 2 (the first conductive part 2A and the second conductive part 2B), the supporting substrate 3 (except at the lower surface of the second metal layer 33), a portion of each of the power terminals 41 to 43, a portion of each control terminal 44, the signal substrate 5 (the first signal substrate 5A and the second signal substrate 5B), the adhesive layer 6 (the first adhesive body 6A and the second adhesive body 6B), the first conductive member 71, the second conductive member 72, and the wires 73 to 76. The resin member 8 is made of a black epoxy resin, for example. The resin member 8 is formed by molding, for example. The resin member 8 has a dimension of about 35 mm to 60 mm in the x direction, about 35 mm to 50 mm in the y direction, and about 4 mm to 15 mm in the z direction, for example. These dimensions are measured at the largest portions in the respective directions. The resin member 8 has a resin obverse surface 81, a resin reverse surface 82, and resin side surfaces 831 to 834.

As shown in FIGS. 6, 7, 9, 11, 12, and 19 to 22, the resin obverse surface 81 and the resin reverse surface 82 are spaced apart from each other in the z direction. The resin obverse surface 81 faces the z2 side, and the resin reverse surface 82 faces the z1 side. The control terminals 44 (the first control terminals 45 and the second control terminals 46) protrude from the resin obverse surface 81. In plan view as shown in FIG. 10, the resin reverse surface 82 has the shape of a frame surrounding the lower surface of the second metal layer 33 of the supporting substrate 3. The lower surface of the second metal layer 33 is exposed from the resin reverse surface 82. In one example, the second metal layer 33 is flush with the resin reverse surface 82. Each of the resin side surfaces 831 to 834 is connected to both of the resin obverse surface 81 and the resin reverse surface 82 and located between them in the z direction. As shown in FIG. 4, for example, the resin side surfaces 831 and 832 are spaced apart from each other in the x direction. The resin side surface 831 faces the x1 side, and the resin side surface 832 faces the x2 side. The two power terminals 43 protrude from the resin side surface 831, and the power terminals 41 and 42 protrude from the resin side surface 832. As shown in FIG. 4, for example, the resin side surfaces 833 and 834 are spaced apart from each other in the y direction. The resin side surface 833 faces the y1 side, and the resin side surface 834 faces the y2 side.

The resin side surface 832 is formed with a plurality of recesses 832a as shown in FIG. 4. In plan view, each recess 832a is recessed in the x direction. One of the recesses 832a is formed between the power terminal 41 and one of the power terminals 42, the other one is formed between the power terminal 41 and the other power terminal 42. Each recess 832a is provided to increase the creepage distance along the resin side surface 832 between the power terminal 41 and the relevant power terminal 42.

As shown in FIGS. 11 and 12, for example, the resin member 8 has a plurality of first projections 851, a plurality of second projections 852, and a resin cavity 86.

The first projections 851 protrude from the resin obverse surface 81 in the z direction. In plan view, the first projections 851 are located at or near the four corners of the resin member 8. Each of the first projections 851 has a first-projection end surface 851a at its end (the end on the z2 side). The first-projection end surfaces 851a of the first projections 851 are parallel (or substantially parallel) to the resin obverse surface 81. The first-projection end surfaces 851a lic in the same plane (x-y plane). Each first projection 851 has the shape of a truncated hollow cone with a bottom, for example. The first projections 851 serve as spacers when the semiconductor device A1 is mounted on, for example, a control circuit board. The control circuit board is a part of a device that uses the power generated by the semiconductor device A1. As shown in FIG. 11, each first projection 851 has a recess 851b and an inner wall surface 851c defining the recess 851b. Each first projection 851 may have a columnar shape, preferably a cylindrical columnar shape. Preferably, the recess 851b has a cylindrical columnar shape, and the inner wall surface 851c defines a single perfect circle in plan view.

The semiconductor device A1 may be fastened to the control circuit board or the like by screws, for example. For this purpose, each first projection 851 may be provided with an internal thread on the inner wall surface 851c of the recess 851b of each first projection 851. For example, an insert nut may be inserted into the recess 851b of each first projection 851.

As shown in FIG. 12, for example, the second projections 852 protrude from the resin obverse surface 81 in the z direction. In plan view, the second projections 852 overlap with the control terminals 44. The metal pin 442 of each control terminal 44 protrudes from a second projection 852. Each second projection 852 has the shape of a truncated cone. Each second projection 852 covers the holder 441 and a portion of the metal pin 442 of a control terminal 44.

As shown in FIG. 11, each resin cavity 86 extends in the z direction from the resin obverse surface 81 to the obverse surface 201 of the first conductive part 2A or the second conductive part 2B. Each resin cavity 86 is tapered from the resin obverse surface 81 to the obverse surface 201 in the z direction, so that the cross section orthogonal to the z direction is gradually smaller. The resin cavities 86 are holes in the resin member 8 and formed at the time of molding the resin member 8.

The resin cavities 86 may be formed when the spaces occupied by pressing members during the molding of the resin member 8 are left unfilled with a melted resin material injected to form the resin member 8. The pressing members, which are used to apply pressing force to the obverse surface 201 at the time of the molding, are inserted into the notches formed in the first wiring parts 721 of the second conductive member 72. In this way, the pressing members can press the supporting conductor 2 (the first conductive part 2A and the second conductive part 2B), without interfering with the second conductive member 72. This can prevent warping of the supporting substrate 3 to which the supporting conductor 2 is bonded.

As shown in FIG. 11, the semiconductor device A1 of the present embodiment includes resin-filled parts 88. The resin-filled parts 88 are formed by filling the resin cavities 86 with a resin material. The resin material forming the resin-filled parts 88 may be the same epoxy resin as that forming the resin member 8, or may be a resin material different from that forming the resin member 8.

The following describes advantages of the joining structures B11 to B14 and the semiconductor device A1.

The joining structures B11 to B14 include the intermediate bonding materials 19a, 19b, 29a, and 29b, respectively. The intermediate bonding materials 19a, 19b, 29a, and 29b have base layers 190a, 190b, 290a, and 290b, respectively. Each of the base layers 190a, 190b, 290a, and 290b contains copper (Cu) as a main component. Thus, the base layers 190a, 190b, 290a, and 290b can conduct heat more efficiently than, for example, a configuration in which each of these layers contains aluminum (Al) as a main component. This makes it possible to provide the joining structures B11 to B14 and the semiconductor device A1 that can conduct heat more easily.

The first surface layers 191a, 191b, 291a, and 291b and the members each corresponding to the first bonding layer contain silver (Ag) as a main component. The second surface layers 192a, 192b, 292a, and 292b and the members each corresponding to the second bonding layer also contain silver (Ag) as a main component. This makes it possible to more reliably join these layers by solid-state bonding and improve the quality of joining structures B11 to B14.

The semiconductor device A1 is configured such that the first switching elements 1A, the second switching elements 1B, the supporting conductor 2, and the supporting substrate 3 are bonded to each other via the joining structures B11 to B14. This makes it possible to dissipate heat efficiently from the first switching elements 1A and the second switching elements 1B to the outside of the semiconductor device A1 via the joining structures B11 and B12, the supporting conductor 2, the joining structures B13 and B14, and the supporting substrate 3.

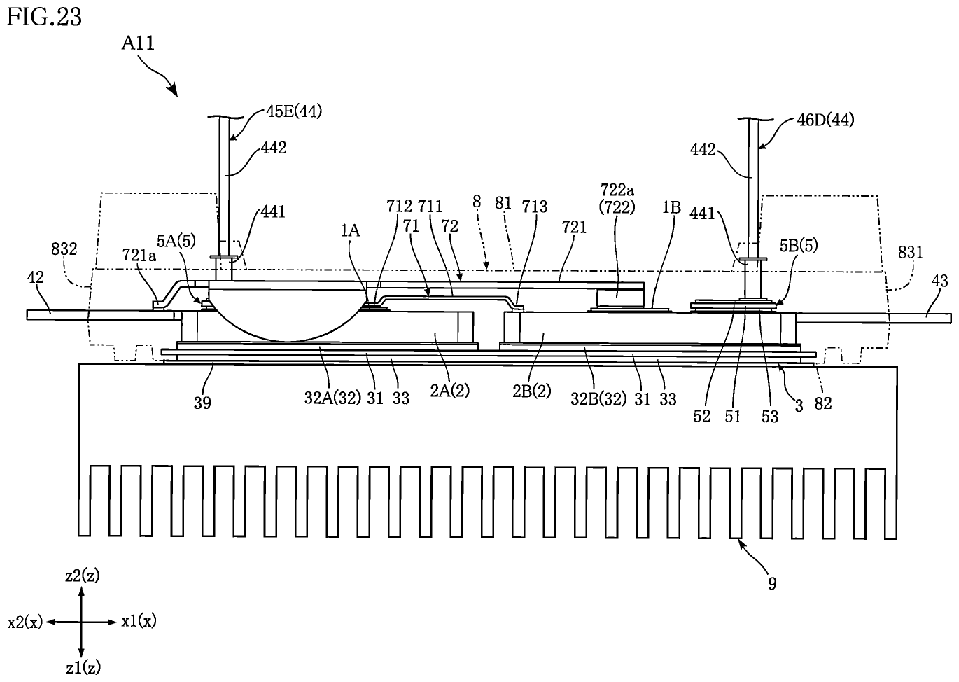

FIGS. 23 to 25 show variations and another embodiment of the present disclosure. In these figures, elements that are the same as or similar to those in the above embodiment are provided with the same reference numerals. The configurations of the elements in each variation and each embodiment can be combined as appropriate as long as the combination does not cause technical inconsistency.

Semiconductor device A1l:

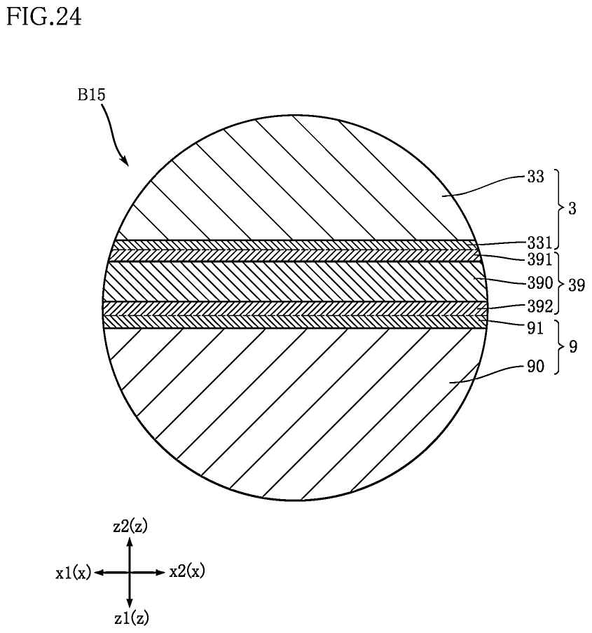

FIG. 23 shows a first variation of the semiconductor device A1. The semiconductor device A1l of the present variation further includes a heat sink 9. The heat sink 9 is provided to dissipate heat more efficiently from the first switching elements 1A and the second switching elements 1B. The heat sink 9 is not limited to a specific configuration. As shown in FIG. 24, the heat sink 9 includes a body 90 and a bonding layer 91.

The body 90 is made of a metal such as aluminum (Al), for example. In the illustrated example, the body 90 has a portion located on the z2 side in the z direction, and a plurality of fins extending from the portion toward the z1 side in the z direction.

As shown in FIG. 23, the heat sink 9 is bonded to the supporting substrate 3 via an intermediate bonding material 39. As shown in FIG. 24, the semiconductor device A11 includes a joining structure B15. The joining structure B15 is a structure in which the supporting substrate 3 as a first bonding target is bonded to the heat sink 9 as a second bonding target via the intermediate bonding material 39.

The intermediate bonding material 39 includes a base layer 390, a first surface layer 391, and a second surface layer 392.

The base layer 390 contains copper (Cu) as a main component. The thickness of the base layer 390 is not particularly limited. The base layer 390 is thicker than each of the first surface layer 391 and the second surface layer 392. The thickness of the base layer 390 is at least 50 μm and at most 300 μm, for example.

The first surface layer 391 is disposed on the surface of the base layer 390 on the z2 side in the z direction. The first surface layer 391 is joined to the supporting substrate 3 by solid-state bonding. The first surface layer 391 mainly contains silver (Ag). The thickness of the first surface layer 391 is not particularly limited. The first surface layer 391 is thinner than the base layer 390. The thickness of the first surface layer 391 is at least 0.1 μm and at most 15 μm, for example.

The supporting substrate 3 further includes a bonding layer 331. The bonding layer 331 corresponds to a first bonding layer in the joining structure B15. The bonding layer 331 is disposed on the surface of the second metal layer 33 on the z1 side in the z direction. The bonding layer 331 is joined to the first surface layer 391 by solid-state bonding. The bonding layer 331 mainly contains silver (Ag). The thickness of the bonding layer 331 is not particularly limited, and may be at least 0.1 μm and at most 15 μm.

The main component of each of the first surface layer 391 and the bonding layer 331 is not limited to a particular metal, as long as the metal allows the first surface layer 391 and the bonding layer 331 to be joined by solid-state bonding.

The second surface layer 392 is disposed on the surface of the base layer 390 on the z1 side in the z direction. The second surface layer 392 is joined to the heat sink 9 by solid-state bonding. The second surface layer 392 mainly contains silver (Ag). The thickness of the second surface layer 392 is not particularly limited. The second surface layer 392 is thinner than the base layer 390. The thickness of the second surface layer 392 is at least 0.1 μm and at most 15 μm, for example.

The bonding layer 91 of the heat sink 9 corresponds to a second bonding layer in the joining structure B15. The bonding layer 91 is disposed on the surface of the body 90 on the z2 side in the z direction. The bonding layer 91 is joined to the second surface layer 392 by solid-state bonding. The bonding layer 91 mainly contains silver (Ag). The thickness of the bonding layer 91 is not particularly limited, and may be at least 0.1 μm and at most 15 μm.

The main component of each of the second surface layer 392 and the bonding layer 91 is not limited to a particular metal, as long as the metal allows the second surface layer 392 and the bonding layer 91 to be joined by solid-state bonding.

The present variation can provide the joining structures B11 to B15 and the semiconductor device A11 that can conduct heat more easily. In addition, the supporting substrate 3 and the heat sink 9 are joined to each other by solid-state bonding via the intermediate bonding material 39. This makes it possible to dissipate heat more efficiently from the first switching elements 1A and the second switching elements 1B to the heat sink 9.

### Joining Structure B2:

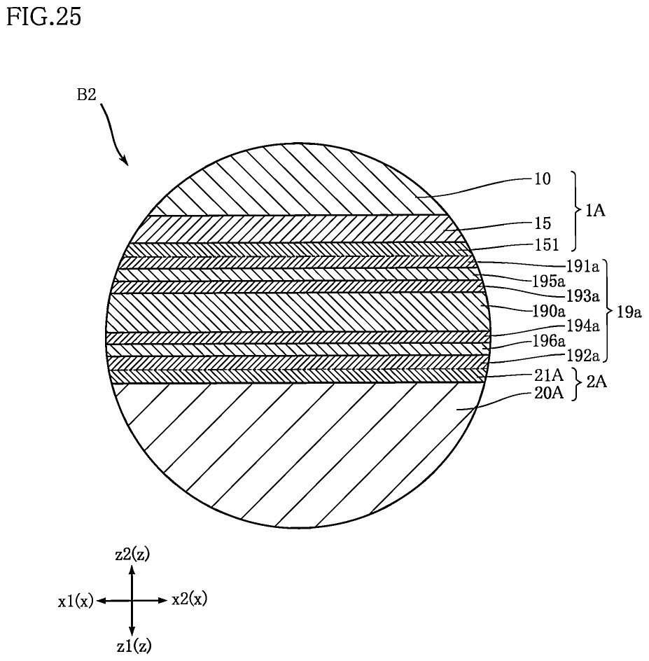

FIG. 25 shows a joining structure according to a second embodiment of the present disclosure. The joining structure B2 of the present embodiment includes a first switching element 1A as a first bonding target, a first conductive part 2A as a second bonding target, and an intermediate bonding material 19a.

The intermediate bonding material 19a of the present embodiment includes a base layer 190a, a first surface layer 191a, a second surface layer 192a, a first intermediate layer 193a, a second intermediate layer 194a, a third intermediate layer 195a, and a fourth intermediate layer 196a.

The first intermediate layer 193a is interposed between the base layer 190a and the first surface layer 191a. The second intermediate layer 194a is interposed between the base layer 190a and the second surface layer 192a. Each of the first intermediate layer 193a and the second intermediate layer 194a contains nickel (Ni) as a main component. The thickness of each of the first intermediate layer 193a and the second intermediate layer 194a is at least 0.1 μm and at most 15 μm, for example.

The third intermediate layer 195a is interposed between the first surface layer 191a and the first intermediate layer 193a. The fourth intermediate layer 196a is interposed between the second surface layer 192a and the second intermediate layer 194a. Each of the third intermediate layer 195a and the fourth intermediate layer 196a contains copper (Cu) as a main component. The thickness of each of the third intermediate layer 195a and the fourth intermediate layer 196a is at least 0.01 μm and at most 10 μm, for example.

The configuration of the intermediate bonding material 19a in the joining structure B2 is applicable to any of the intermediate bonding materials 19b, 29a, 29b, and 39 described above.

The present embodiment can provide the joining structure B2 that can conduct heat more easily. As can be understood from the present embodiment, the joining structure of the present disclosure is not limited to a specific configuration.

The joining structure and the semiconductor device according to the present disclosure are not limited to the above embodiments. Various design changes can be made to the specific configurations of the elements of the joining structure and the semiconductor device according to the present disclosure. The present disclosure includes the embodiments described in the following clauses.

Clause 1. A joining structure comprising:
a first bonding target including a first bonding layer;
a second bonding target including a second bonding layer; and an intermediate bonding material interposed between the first bonding target and the second bonding target, wherein the intermediate bonding material includes a base layer, and a first surface layer and a second surface layer disposed on respective sides of the base layer, the first bonding layer and the first surface layer are joined to each other by solid-phase bonding, the second bonding layer and the second surface layer are joined to each other by solid-phase bonding, and the base layer contains Cu as a main component.

Clause 2. The joining structure according to clause 1, wherein each of the first bonding layer and the first surface layer contains Ag as a main component.

Clause 3. The joining structure according to clause 1 or 2, wherein each of the second bonding layer and the second surface layer contains Ag as a main component.

Clause 4. The joining structure according to any of clauses 1 to 3, wherein the base layer is thicker than the first surface layer.

Clause 5. The joining structure according to any of clauses 1 to 4, wherein the base layer is thicker than the second surface layer.

Clause 6. The joining structure according to any of clauses 1 to 5, wherein the first bonding target further includes a first body containing Cu as a main component.

Clause 7. The joining structure according to any of clauses 1 to 6, wherein the second bonding target further includes a second body containing Cu as a main component.

Clause 8. The joining structure according to any of clauses 1 to 7, wherein the intermediate bonding material further includes a first intermediate layer interposed between the base layer and the first surface layer.

Clause 9. The joining structure according to clause 8, wherein the intermediate bonding material further includes a second intermediate layer interposed between the base layer and the second surface layer.

Clause 10. The joining structure according to clause 9, wherein the intermediate bonding material further includes a third intermediate layer interposed between the first surface layer and the first intermediate layer.

Clause 11. The joining structure according to clause 10, wherein the intermediate bonding material further includes a fourth intermediate layer interposed between the second surface layer and the second intermediate layer.

Clause 12. The joining structure according to clause 11, wherein each of the first intermediate layer and the second intermediate layer contains Ni as a main component.

Clause 13. The joining structure according to clause 12, wherein each of the third intermediate layer and the fourth intermediate layer contains Cu as a main component.

Clause 14. A semiconductor device comprising:
a semiconductor element;
a conductive part; and
a supporting substrate, wherein the semiconductor device is provided with the joining structure according to any of clauses 1 to 13.

Clause 15. The semiconductor device according to clause 14, wherein the joining structure includes the semiconductor element as the first bonding target and the conductive part as the second bonding target.

Clause 16. The semiconductor device according to clause 14 or 15, wherein the joining structure includes the conductive part as the first bonding target and the supporting substrate as the second bonding target.

Clause 17. The semiconductor device according to any of clauses 14 to 16, further comprising a heat sink, wherein the joining structure includes the supporting substrate as the first bonding target and the heat sink as the second bonding target.

### REFERENCE NUMERALS

A1, A11: Semiconductor device
B1, B11, B12, B13, B14, B15: Joining structure
B2, B3, B4: Joining structure
1: Semiconductor element
1A: First switching element
1B: Second switching element
2: Supporting conductor
2A: First conductive part
2B: Second conductive part
3: Supporting substrate
5: Signal substrate
5A: First signal substrate
5B: Second signal substrate
6: Adhesive layer
6A: First adhesive body
6B: Second adhesive body
8: Resin member
9: Heat sink
10a: Element obverse surface
10b: Element reverse surface
11: First obverse-surface electrode
12: Second obverse-surface electrode
13: Third obverse-surface electrode
15: Reverse-surface electrode
17: Thermistor
19a: Intermediate bonding material
19b: Intermediate bonding material
20A, 20B: Body layer
20b: Intermediate bonding material
21A, 21B, 22A, 22B: Bonding layer
29a, 29b: Intermediate bonding material
31: Insulating layer
32: First metal layer
32A: First part
32B: Second part
33: Second metal layer
39: Intermediate bonding material
41, 42, 43: Power terminal
44: Control terminal
45: First control terminal
45A: First drive terminal
45B, 45C, 45D, 45E: First sensing terminal
46: Second control terminal
46A: Second drive terminal
46B, 46C, 46D, 46E: Second sensing terminal
51: Insulating substrate
51a: Obverse surface
51b: Reverse surface
52: First metal layer
53: Second metal layer
61: Insulating layer
61a: Obverse surface
61b: Reverse surface
62, 63: Adhesive layer
71: First conductive member
72: Second conductive member
73, 74, 75, 76: Wire
81: Resin obverse surface
82: Resin reverse surface
86: Resin cavity
88: Resin-filled part
90: Body
91: Bonding layer
151: Bonding layer
190a, 190b: Base layer
191a, 191b: First surface layer
192a, 192b: Second surface layer
193a: First intermediate layer
194a: Second intermediate layer
195a: Third intermediate layer
196a: Fourth intermediate layer
201: Obverse surface
202: Reverse surface
290a, 290b: Base layer
291a, 291b: First surface layer
292a, 292b: Second surface layer
321A, 321B, 331: Bonding layer
390: Base layer
391: First surface layer
392: Second surface layer
441: Holder
442: Metal pin
449: Conductive bonding material
521 to 526: Wiring layer
711: Main part
711a: Opening
712: First connecting end
712a: Opening
713: Second connecting end
719: Conductive bonding material
721: First wiring part
721a: First end
722: Second wiring part
722a: Recessed region
723: Third wiring part
724: Fourth wiring part
729: Conductive bonding material
831: Resin side surface
832: Resin side surface
832a: Recess
833, 834: Resin side surface
851: First projection
851a: First-projection end surface
851b: Recess
851c: Inner wall surface
852: Second projection

1. A joining structure comprising:
a first bonding target including a first bonding layer;
a second bonding target including a second bonding layer; and
an intermediate bonding material interposed between the first bonding target and the second bonding target,
wherein the intermediate bonding material includes a base layer, and a first surface layer and a second surface layer disposed on respective sides of the base layer,
the first bonding layer and the first surface layer are joined to each other by solid-phase bonding,
the second bonding layer and the second surface layer are joined to each other by solid-phase bonding, and
the base layer contains Cu as a main component.

2. The joining structure according to claim 1, wherein each of the first bonding layer and the first surface layer contains Ag as a main component.

3. The joining structure according to claim 1, wherein each of the second bonding layer and the second surface layer contains Ag as a main component.

4. The joining structure according to claim 1, wherein the base layer is thicker than the first surface layer.

5. The joining structure according to claim 1, wherein the base layer is thicker than the second surface layer.

6. The joining structure according to claim 1, wherein the first bonding target further includes a first body containing Cu as a main component.

7. The joining structure according to claim 1, wherein the second bonding target further includes a second body containing Cu as a main component.

8. The joining structure according to claim 1, wherein the intermediate bonding material further includes a first intermediate layer interposed between the base layer and the first surface layer.

9. The joining structure according to claim 8, wherein the intermediate bonding material further includes a second intermediate layer interposed between the base layer and the second surface layer.

10. The joining structure according to claim 9, wherein the intermediate bonding material further includes a third intermediate layer interposed between the first surface layer and the first intermediate layer.

11. The joining structure according to claim 10, wherein the intermediate bonding material further includes a fourth intermediate layer interposed between the second surface layer and the second intermediate layer.

12. The joining structure according to claim 11, wherein each of the first intermediate layer and the second intermediate layer contains Ni as a main component.

13. The joining structure according to claim 12, wherein each of the third intermediate layer and the fourth intermediate layer contains Cu as a main component.

14. A semiconductor device comprising:
a semiconductor element;
a conductive part; and
a supporting substrate,
wherein the semiconductor device is provided with the joining structure according to claim 1.

15. The semiconductor device according to claim 14, wherein the joining structure includes the semiconductor element as the first bonding target and the conductive part as the second bonding target.

16. The semiconductor device according to claim 14, wherein the joining structure includes the conductive part as the first bonding target and the supporting substrate as the second bonding target.

17. The semiconductor device according to claim 14, further comprising a heat sink,
wherein the joining structure includes the supporting substrate as the first bonding target and the heat sink as the second bonding target.
